(19) United States
(12) Patent Application Publication
(10) Pub. No.: US 2016/0103369 A1
(43) Pub. Date: Apr. 14, 2016

(54) LIQUID CRYSTAL DISPLAY DEVICE AND MANUFACTURING METHOD THEREOF

(71) Applicant: Japan Display Inc., Tokyo (JP)

(72) Inventor: Yasuo IMANISHI, Tokyo (JP)

(21) Appl. No.: 14/878,305

(22) Filed: Oct. 8, 2015

(30) Foreign Application Priority Data
Oct. 8, 2014 (JP) 2014-207246

(51) Int. Cl. G02F 1/1337; H01L 27/12; G02F 1/1368

(52) U.S. Cl. CPC G02F 1/133788; G02F 1/1368; G02F 1/133711; H01L 27/1262

(57) ABSTRACT

There is provided a high-quality liquid crystal display device that improves viewing angle characteristics and display contrast in low afterglow. A liquid crystal display device includes: a TFT substrate having a pixel electrode and a TFT and formed with an alignment film on a pixel; a counter substrate disposed opposite to the TFT substrate and formed with an alignment film on a topmost surface on the TFT substrate side; and a liquid crystal sandwiched between the alignment film of the TFT substrate and the alignment film of the counter substrate. The alignment film is a material that is enabled to provide liquid crystal alignment regulating force by applying polarized light. The topmost surface layer of the photo-alignment film has liquid crystal alignment regulating force, and the photo-alignment film has little optical anisotropy.

### CLAIM OF PRIORITY

The present application claims priority from Japanese Patent Application JP 2014-207246 filed on Oct. 8, 2014, the content of which is hereby incorporated by reference into this application.

### FIELD OF THE INVENTION

The present invention relates to a high-quality liquid crystal display device that improves viewing angle characteristics and display contrast and a manufacturing method thereof.

### BACKGROUND OF THE INVENTION

Since liquid crystal display devices have merits such as high display quality, reduced thickness, reduced weight, and low power consumption, the use applications of the devices are expanding, and the devices are used for various use applications including mobile device monitors such as a mobile telephone monitor, digital still camera monitor, personal computer monitor, monitor intended for printing and design, medical monitor, and liquid crystal television. In association with the expansion of these use applications, it is demanded to further improve the image quality and the quality of the liquid crystal display device, and it is strongly demanded to improve luminance and to decrease power consumption by achieving higher transmittances specifically. Moreover, in association with the spread of the liquid crystal display device, a decrease in costs is also demanded.

In general, images are displayed on the liquid crystal display device in which an electric field is applied to the liquid crystal molecules of a liquid crystal layer sandwiched between a pair of substrates to change the alignment direction of the liquid crystal molecules and the change causes changes in the optical properties of the liquid crystal layer for displaying images. The alignment direction of the liquid crystal molecules when the electric field is not applied is defined by an alignment film that the surface of a polyimide thin film is rubbed. Conventionally, in an active matrix liquid crystal display device having a switching element such as a thin film transistor (TFT) for each pixel, an electrode is individually provided on a pair of substrates between which a liquid crystal layer is sandwiched, an electric field is set to a so-called vertical electric field that the direction of the electric field applied to the liquid crystal layer is almost perpendicular to the substrate surface, and images are displayed using the optical rotatory power of liquid crystal molecules forming the liquid crystal layer. For representative liquid crystal display devices in a vertical field mode, liquid crystal display devices in a twisted nematic (TN) mode and a vertical alignment (VA) mode are known.

In liquid crystal display devices in the TN mode and the VA mode, one of large problems is a narrow viewing angle. Therefore, as display modes to achieve wider viewing angles, an in-plane switching (IPS) mode and a fringe-field switching (FFS) mode are known.

The IPS mode and the FFS mode are a so-called transverse electric field display mode in which a comb tooth electrode is formed on one of a pair of substrates and an electric field to be generated has a component nearly in parallel with the substrate surface. Liquid crystal molecules forming a liquid crystal layer are rotated in a plane nearly in parallel with the substrate, and images are displayed using the birefringence of the liquid crystal layer. The IPS mode and the FFS mode are advantageous in that the viewing angle is wide and the load capacity is low as compared with the previously existing TN mode because of the in-plane switching of the liquid crystal molecules, for example. The liquid crystal display devices in the IPS mode and the FFS mode are regarded as new promising devices that replace liquid crystal display devices in the TN mode, and are in a rapid progress in these years.

In the liquid crystal display device, the orientation state of the liquid crystal molecules in the liquid crystal layer is controlled by the presence or absence of an electric field. In other words, upper and lower polarizers provided on the outer sides of the liquid crystal layer are set in the completely orthogonal state, a phase difference is generated due to the orientation state of the liquid crystal molecules between the polarizers, and light and dark states are formed. In order to control the orientation state in which no electric field is applied to the liquid crystal molecules, this control is achieved in which a polymer thin film called an alignment film is formed on the surface of the substrate and the liquid crystal molecules are arrayed in the array direction of polymers due to an intermolecular interaction caused by van der Waals force between a polymer chain and the liquid crystal molecule on the interface. This interaction is also referred to as alignment regulating force, the provision of a liquid crystal aligning function, or an alignment process.

Polyimide is often used for an alignment film of a liquid crystal display device. In a forming method of the alignment film, polyamic acid that is a polyimide precursor is solved in various solvents, and coated over a substrate by spin coating or printing, the substrate is heated at high temperature at a temperature of 200° C. or more, the solvents are removed, and the polyamic acid is imidized to polyimide by cyclization. The thin film has a thickness of about 100 nm in the imidization. The surface of this polyimide thin film is rubbed in a certain direction using a rubbing cloth, polyimide polymer chains on the surface are aligned in the rubbing direction, and then it is achieved that polymers on the surface are in a high anisotropic state. However, there are problems such as the occurrence of static electricity and foreign substances caused by rubbing and ununiform rubbing caused by irregularities on the surface of the substrate, and a photo-alignment method is becoming adopted in which polarized light is used to control molecular orientations with no need to contact a rubbing cloth.

The photo-alignment method for a liquid crystal alignment film include photoisomerization type photo-alignment that the geometry in a molecule is changed by applying a polarized ultraviolet ray like azo dye and photodimerization type photo-alignment that molecular frameworks generate a chemical bond caused by a polarized ultraviolet ray such as cinnamic acid, coumalin, and chalcone, and other types. Photodecomposition type photo-alignment is suited to the photo-alignment of polyimide that is reliable and achieves results as a liquid crystal alignment film, in which a polarized ultraviolet ray is applied to polymers, only polymer chains arranged in the polarization direction are broken and decomposed and molecular chains in the direction perpendicular to the polarization direction are left.

This method is studied in various liquid crystal display modes. For the IPS mode in the various modes, Japanese Patent Application Laid-Open No. 2004-206091 discloses a liquid crystal display device that decreases the occurrence of display failures caused by changes in the initial alignment direction, stabilizes liquid crystal alignment, and improves mass production, a contrast ratio, and image quality. In Japanese Patent Application Laid-Open No. 2004-206091, the function of controlling molecular orientations is provided by performing an alignment process in which at least one secondary treatment of heating, infrared irradiation, far infrared irradiation, electron beam irradiation, and radiation exposure is applied to polyimide or polyamic acid formed of aromatic diamine, cyclobutanetetracarboxylic dianhydride, and a derivative of cyclobutanetetracarboxylic dianhydride, polyamic acid formed of aromatic diamine and cyclobutanetetracarboxylic dianhydride, or polyamic acid formed of aromatic diamine and a derivative of cyclobutanetetracarboxylic dianhydride.

More specifically, Japanese Patent Application Laid-Open No. 2004-206091 describes that the effect is further effectively exerted when at least one process of heating, infrared irradiation, far infrared irradiation, electron beam irradiation, and radiation exposure is performed in a temporal overlap of a polarized light irradiation process, and that the effect is also effectively exerted when an alignment control film is subjected to an imidization baking process and the polarized light irradiation process in a temporal overlap. More specifically, Japanese Patent Application Laid-Open No. 2004-206091 describes that in the case where a liquid crystal alignment film is subjected to at least one process of heating, infrared irradiation, far infrared irradiation, electron beam irradiation, and radiation exposure in addition to polarized light irradiation, the temperature of the alignment control film is desirably in a range of a temperature of 100 to 400° C., and more desirably in a range of a temperature of 150 to 300° C. The processes of heating, infrared irradiation, and far infrared irradiation can be combined with the imidization baking process of the alignment control film, which is effective.

However, the liquid crystal display device using these photo-alignment films has a short history compared with the case of using rubbed alignment films, and sufficient findings are not available for long-term display quality over several years as a practical liquid crystal display device. In other words, the fact is that the relationship between image quality failures and problems unique to the photo-alignment film, which are not obvious in the initial stage of manufacture, are rarely reported.

### SUMMARY OF THE INVENTION

The present inventors thought that in order to implement a liquid crystal display device of high quality and high definition in future, photo-alignment techniques became important, and conducted detailed studies on problems in the application of the photo-alignment techniques to liquid crystal display devices. As a result, the following was revealed. In the previously existing photo-alignment techniques, ultraviolet rays used for photo-alignment processes are effective in producing liquid crystal alignment regulating force on the surface of the alignment film. However, ultraviolet rays also work in the inside of the film, for which a long-term structural stability is necessary, and the ultraviolet rays optically degrade the inside of the film, and at the same time, optical anisotropy is excessively formed in the alignment film itself. Thus, the ultraviolet rays affect the viewing angle characteristics and contrast of the liquid crystal display device, leading to problems to cope with products in future.

It is an object of the present invention to provide a liquid crystal display device that can stably provide excellent display characteristics using a photo-alignment technique and a manufacturing method thereof.

In the present application, a brief description of a representative configuration of some aspects to be disclosed is as follows. In other words, an object of the present invention is achieved by a liquid crystal display device including: a TFT substrate having a pixel electrode and a TFT and formed with an alignment film on a pixel; a counter substrate disposed opposite to the TFT substrate and formed with an alignment film on a topmost surface on the TFT substrate side; and a liquid crystal sandwiched between the alignment film of the TFT substrate and the alignment film of the counter substrate. In the liquid crystal display device, the alignment film is a material that is enabled to provide liquid crystal alignment regulating force by applying polarized light. The topmost surface layer of the photo-alignment film has liquid crystal alignment regulating force, and the photo-alignment film has little optical anisotropy. More detailed configurations of the liquid crystal display device according to an aspect of the present invention are as follows.

In other words, in the liquid crystal display device, the alignment regulating force on the surface of the photo-alignment film has an anchoring strength of 1.0×10⁻³ J/m² or greater obtained from an optical twist angle.

Moreover, in the liquid crystal display device, optical anisotropy of the photo-alignment film is smaller than 1.0 nm in a retardation value.

Furthermore, in the liquid crystal display device, optical anisotropy of the photo-alignment film is 0.1 or less in an order parameter.

In addition, in the liquid crystal display device, a size of a surface irregularity of the photo-alignment film is one nanometer or less in a root mean square.

Moreover, in the liquid crystal display device, the photo-alignment film is formed only on any one of the TFT substrate and the counter substrate.

Furthermore, in the liquid crystal display device, the alignment film is a photodecomposition type photo-alignment film.

In addition, in the liquid crystal display device, the alignment film is a photodecomposition type photo-alignment film containing polyimide given by Chemical formula 1,

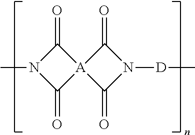

where a formula in brackets expresses a chemical structure of a repetition unit, numerical subscript n expresses a number of the repetition unit, N expresses a nitrogen atom, O expresses an oxygen atom, A expresses a quadrivalent organic group containing a cyclobutane ring, and D expresses a divalent organic group.

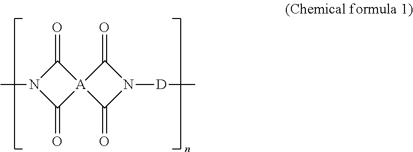

Moreover, in the liquid crystal display device, the alignment film has a structure in which two types of alignment films are stacked in a two-layer structure formed of a photo-alignable photo-alignment upper layer and a low resistive under layer having a resistivity lower than a resistivity of the photo-alignment upper layer.

Furthermore, in the liquid crystal display device, the liquid crystal display device is an IPS mode liquid crystal display device.

In addition, a manufacturing method of a liquid crystal display device according to an aspect of the present invention is a manufacturing method of a liquid crystal display device including a TFT substrate having a pixel electrode and a TFT and formed with an alignment film on a pixel; a counter substrate disposed opposite to the TFT substrate and formed with an alignment film on a topmost surface on the TFT substrate side; and a liquid crystal sandwiched between the alignment film of the TFT substrate and the alignment film of the counter substrate. The method includes the steps of: preparing the TFT substrate having the pixel electrode and the TFT; forming the alignment film on the TFT substrate or the counter substrate; applying a polarized ultraviolet ray to the alignment film and oxidizing the alignment film to provide a state in which a topmost surface layer of the photo-alignment film has liquid crystal alignment regulating force and the photo-alignment film has little optical anisotropy; attaching the TFT substrate attached with the alignment film provided with the alignment regulating force to the counter substrate; and filling a liquid crystal between the TFT substrate and the counter substrate in the attaching step or after the attaching step.

Moreover, in the manufacturing method of a liquid crystal display device, a cross-linker is added in the alignment film; and cross-linking is performed after the step of applying the polarized ultraviolet ray to the alignment film to the step of attaching the TFT substrate to the counter substrate.

Furthermore, in the manufacturing method of a liquid crystal display device, heat treatment is not performed at a temperature of 180° C. or more after the step of applying the polarized ultraviolet ray to the alignment film to the step of attaching the TFT substrate to the counter substrate.

In addition, in the manufacturing method of a liquid crystal display device, heat treatment is not performed at a temperature of 120° C. or more after the step of applying the polarized ultraviolet ray to the alignment film to the step of attaching the TFT substrate to the counter substrate.

The state referred here in which the topmost surface layer of the photo-alignment film has liquid crystal alignment regulating force and the photo-alignment film has little optical anisotropy is a state in which two characteristics below are provided on the surface of the photo-alignment film and in the inside of the film. In other words, the surface state of the alignment film having the liquid crystal alignment regulating force is a state in which in forming a liquid crystal display device, a monodomain liquid crystal orientation state can be obtained in a pixel region in a predetermined orientation. It is also possible that the level of the alignment regulating force can be quantified by anchoring strength obtained from the measurement values of the optical twist angle as described in Japanese Patent Application Laid-Open No. 2007-164153, for example.

On the other hand, the state in which the photo-alignment film has little optical anisotropy is a state in which in the case where optical anisotropy in the film surface of the entire alignment film is measured, little anisotropy is observed. The level of the optical anisotropy can be found from retardation values described in Japanese Patent Application Laid-open No. 2007-164153, for example. Alternatively, the level of the optical anisotropy can be found from the description in Japanese Patent Application Laid-Open No. 2011-114470, for example, in which the polarized ultraviolet absorption spectrum of the alignment film is measured and the level is found from an absorption dichroic ratio at an ultraviolet absorption maximum wavelength.

In general, when the liquid crystal alignment regulating force is produced on the surface of the alignment film, the alignment film is in the state in which the molecular orientation anisotropy of molecules forming the alignment film is produced in the inside of the film. The state in which optical anisotropy is not produced on the entire alignment film is a state in which little anisotropy is observed in the case where the molecular orientation anisotropy of the entire film is observed. This state can be easily implemented in the case where alignment regulating force is produced by a rubbing method as described in Japanese Patent Application Laid-Open No. 2007-164153, for example. However, it is difficult to achieve both of high liquid crystal alignment regulating force and low optical anisotropy in the photo-alignment method. This is because in the rubbing method, molecular orientation anisotropy is induced only on the surface of the alignment film which a rubbing cloth directly contacts, whereas in the photo-alignment method, anisotropy is generated also on the molecular orientation distribution in the inside of the film as polarized ultraviolet rays used for alignment reach the inside of the film.

As described in Japanese Patent Application Laid-Open No. 2011-114470, for example, the weakness of the liquid crystal alignment regulating force can be conformed as a so-called afterglow phenomenon that in the case where the same image is displayed on the screen of a liquid crystal display device for long hours, the display of the image is stopped, and then gray is displayed on the entire screen, for example, the previous image is persistent on the screen. Moreover, when the alignment film has optical anisotropy, the optical anisotropy causes a residual phase difference, which is a factor in the degradation of display characteristics, leading to a decrease in the viewing angle characteristics. A retardation plate for compensating the degradation is necessary to have a small phase difference that is 80 nm or less, generally leading to problems in that a liquid crystal display device is difficult to be manufactured and costs are expensive, for example. In other words, in order that the image quality of a liquid crystal display device using a photo-alignment film is equivalent to or exceeds the image quality of a liquid crystal display device using a rubbing film, it is necessary to make both of the liquid crystal alignment regulating force on the topmost surface of the alignment film and the optical anisotropy of the entire alignment film at least equivalent to those of one using a rubbing film.

As a result of dedicated investigation conducted by the present inventors, the present inventors realized a photo-alignment film that satisfies these two characteristics, which were difficult to be realized by previously existing manufacturing methods. More specifically, in order to obtain the performance of a liquid crystal display device equivalent to or exceeding ones using a rubbing film, the anchoring strength is desirably 1.0×10⁻³ J/m² or greater, and more desirably 3.0×10³ J/m² or greater. Moreover, the optical anisotropy of the alignment film desirably has a retardation value smaller than 1.0 nm, for example, and more desirably has a retardation value smaller than 0.5 nm. Alternatively, the optical anisotropy of the alignment film desirably has an order parameter of 0.1 or less, for example, and more desirably has an order parameter of 0.05 or less.

Furthermore, as described in Japanese Patent Application Laid-Open No. 2007-164153, for example, the residual phase difference greatly affects display devices in the TN mode or in the IPS mode more than display devices in the VA mode in which the liquid crystal is vertically oriented on the surface of the alignment film. In the liquid crystal display device using the photo-alignment film according to an aspect of the present invention, the effect of decreasing the optical anisotropy of the entire alignment film as in an aspect of the present invention can be more noticeably achieved in display devices in the TN mode or IPS mode.

In addition, in order to decrease light leakage induced by the disturbance in alignment on the interface between the liquid crystal layer and the surface of the alignment film caused by the disturbance in the flatness of the surface of the alignment film, the size of a surface irregularity is desirably one nanometer or less in a root mean square, and more desirably 0.5 nm or less.

Moreover, it may be fine that the photo-alignment film according to an aspect of the present invention is formed only on any one of the TFT substrate and the counter substrate of the liquid crystal display device. In this case, for the alignment film of the other substrate, various alignment films can be used including a rubbed alignment film or a photo-alignment film by previously existing methods. This is because the application of a manufacturing method of a photo-alignment film according to an aspect of the present invention as it is sometimes causes damage on the members other than the alignment film such as the case where ultraviolet rays in photo-alignment degrades the pigment of a color filter below the photo-alignment film, for example. When this case is considered, the effect of improving image quality is exerted also in the case where the manufacturing method according to an aspect the present invention is not applied to a substrate having a device structure possibly damaged and the manufacturing method according to an aspect the present invention is applied only to a substrate in other structures.

Furthermore, polyimide referred here is a polymer compound expressed by Chemical formula 1, where a formula in brackets expresses the chemical structure of a repetition unit, numerical subscript n expresses the number of the repetition unit, N expresses a nitrogen atom, O expresses an oxygen atom, A expresses a quadrivalent organic group containing a cyclobutane ring, and D expresses a divalent organic group. Examples of the structure of A can include: an aromatic cyclic compound such as a phenylene ring, naphthalene naphthalene ring, and anthracene ring; an aliphatic cyclic compound such as cyclobutane, cyclopentane, and cyclohexane; or a compound that a substituent group is bonded to these compounds, for example. In addition, examples of the structure of D can include: an aromatic cyclic compound such as phenylene, biphenylene, oxybiphenylene, biphenyleneamine, naphthalene, and anthracene; an aliphatic cyclic compound such as cyclohexene and bicyclohexene; or a compound that a substituent group is bonded to these compounds, for example.

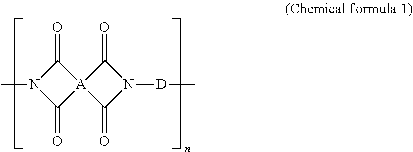

These polyimides are coated on various base layers held on a substrate in a state of a polyimide precursor. Moreover, the polyimide precursor referred here is polyamic acid or a polyamic acid ester polymer compound expressed by Chemical formula 2. Where H is hydrogen atom, R₁ and R₂ are hydrogen or an alkyl chain, —CₘH₂ₘ₊₁, and m=1 or 2.

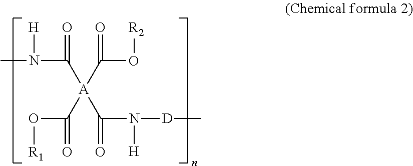

In order to form such an alignment film, a thin film is formed using a typical forming method of a polyimide alignment film, for example, in which a base layer is purified using various surface treatment methods such as a UV/ozone method, excimer UV method, and oxygen plasma method, the precursor of the alignment film is coated using various printing methods such as screen printing, flexographic printing, and ink jet printing, the film is subjected to a leveling process to provide a uniform film thickness under predetermined conditions, and then the film is heated at a temperature of 180° C. or more, for example, to imidize a precursor polyamide to polyimide.

In the formation, it is also possible to add various additives in advance in order to improve the wettability to the base layer and to promote the imidization reaction, for example. Furthermore, it is possible to produce the alignment regulating force on the surface of the polyimide alignment film by applying polarized ultraviolet rays or by moderate postprocessing using desired schemes. Two substrates attached with the alignment film thus formed are attached to each other with a certain gap maintained, and the gap portion is filled with a liquid crystal. Alternatively, a liquid crystal is dropped before the substrates are attached to each other, and then the substrates are attached to each other. After attaching the substrates, the end portions of the substrates are sealed, and a liquid crystal panel is completed. Optical films such as a polarizer and a retardation plate are attached to the panel, a drive circuit, a backlight, and other components are mounted, and then a liquid crystal display device is obtained.

Moreover, a material including a plurality of components can be used for the photo-alignment film according to an aspect of the present invention in order to improve performance. For example, such an alignment film material is selected to provide a structure in which two types of alignment films are stacked in a two-layer structure formed of a photo-alignable photo-alignment upper layer and a low resistive under layer having a resistivity lower than a resistivity of the photo-alignment upper layer. Thus, the resistance of the entire alignment film is decreased, and it is possible to prevent charges from being stored caused by driving the liquid crystal display device. Moreover, the under layer alignment film has no photo-alignment properties, and it is possible to further decrease the level of the optical anisotropy of the entire alignment film.

Furthermore, a cross-linking additive or an alignment film material having a cross-linking functional group is added to the photo-alignment film according to an aspect of the present invention, and it is also possible to improve the mechanical strength of the photo-alignment film finally obtained and to improve long term stability of the alignment regulating force. In this case, cross-linking is performed after the step of applying the polarized ultraviolet ray to the alignment film to the step of attaching the TFT substrate to the counter substrate, and it is possible to finish an alignment film that easily provides stability as the level of the alignment regulating force is improved.

In the case where cross-linking is performed before applying ultraviolet rays, it is not possible to remove molecular framework portions subjected to optical cutting even though polarized ultraviolet rays are applied because the polyamide of the polyimide precursor forms a cross-link structure, and it is not possible to obtain alignment regulating force. In the case where cross-linking is performed after the process of attaching the TFT substrate to the counter substrate, problems arise in that film contraction stress is produced in association with the cross-link reaction, and distortion is produced on the attached seal portions. More specifically, micro cracks are produced on the seal in a long term storage test, and external moisture is easily entered to the liquid crystal layer, for example.

In performing such cross-linking, it is necessary to cause a cross-linking reaction by light or heat. However, it is necessary to perform cross-linking without impairing the photo-alignment properties already formed. As a result of dedicated investigation conduced by the present inventors, the following was revealed. Desirably, heat treatment is not performed at a temperature of 180° C. or more, and more desirably, heat treatment is not performed at a temperature of 120° C. or more. This is because in the case where the photo-alignment film is heated at a temperature of 180° C. or more, it becomes difficult to achieve both of high alignment regulating force and low optical anisotropy, which are an object of the present invention, because of the induction of the occurrence of new optical anisotropy caused by the thermal deformation of the photo-alignment film itself, for example. It was revealed that in the case where the photo-alignment film is heated at a temperature of 120° C. or more, the molecular orientation in the inside of the film is stable but the molecular orientation on the topmost layer of the film is relaxed, and the liquid crystal alignment regulating force is decreased.

According to an aspect of the present invention, it is possible to provide a high-quality liquid crystal display device that achieves both of high liquid crystal alignment regulating force and low optical anisotropy, and has wide viewing angle characteristics, high display contrast, excellent stability, and less afterglow.

### BRIEF DESCRIPTION OF THE DRAWINGS

FIG. 1 is a schematic diagram of the structure of an alignment film of a liquid crystal display device according to an embodiment of the present invention;

FIG. 2A is a schematic cross sectional diagram of the intensity of ultraviolet rays in the alignment film;

FIG. 2B is a schematic diagram of a process of photo-alignment on the surface of the alignment film;

FIG. 2C is a schematic diagram of a process of photo-alignment in the inside of the alignment film;

FIG. 3A is a schematic block diagram of an exemplary schematic configuration of a liquid crystal display device according to an embodiment of the present invention;

FIG. 3B is a schematic circuit diagram of an exemplary circuit configuration of a single pixel of a liquid crystal display panel;

FIG. 3C is a schematic plan view of an exemplary schematic configuration of the liquid crystal display panel;

FIG. 3D is a cross sectional view of an exemplary cross sectional configuration taken along line A-A′ in FIG. 3C;

FIG. 4 is a schematic diagram of an exemplary schematic configuration of an IPS mode liquid crystal display panel according to an embodiment of the present invention;

FIG. 5 is a schematic diagram of an exemplary schematic configuration of an FFS mode liquid crystal display panel according to an embodiment of the present invention;

FIG. 6 is a schematic diagram of an exemplary schematic configuration of a VA mode liquid crystal display panel according to an embodiment of the present invention;

FIG. 7 is a flowchart of the manufacturing process steps of a liquid crystal display device using an alignment film according to an embodiment of the present invention;

FIG. 8 is a schematic diagram of an optical system for the measurement of anchoring investigated in the present invention;

FIG. 9 is a schematic diagram of an optical system for the measurement of retardation investigated in the present invention;

FIG. 10 is a schematic diagram of an optical system for the measurement of order parameters investigated in the present invention;

FIG. 11 is Table 1 of evaluation results obtained from a first embodiment of the present invention;

FIG. 12 is Table 2 of evaluation results obtained from the first embodiment of the present invention;

FIG. 13 is Table 3 of evaluation results obtained from a second embodiment of the present invention;

FIG. 14 is Table 5 of evaluation results obtained from a third embodiment of the present invention;

FIG. 15 is Table 6A of evaluation results in the case of performing only heat treatment as postprocessing after UV irradiation in a fourth embodiment of the present invention;

FIG. 16 is Table 6B of evaluation results in the case of performing heat treatment after hypochlorous acid solution processing as postprocessing after UV irradiation in the fourth embodiment of the present invention;

FIG. 17 is Table 6C of evaluation results in the case of performing hypochlorous acid solution processing after heat treatment as postprocessing after UV irradiation in the fourth embodiment of the present invention;

FIG. 18 is Table 7 of evaluation results obtained from a fifth embodiment of the present invention; and

FIG. 19 is Table 8 of evaluation results obtained from a sixth embodiment of the present invention.

### DETAILED DESCRIPTION OF THE PREFERRED EMBODIMENTS

In the following, the present invention will be described in detail with reference to embodiments and the drawings. It is noted that in all the drawings for explaining the embodiments, components having the same functions are designated the same reference numerals and signs, and the overlapping description will be omitted.

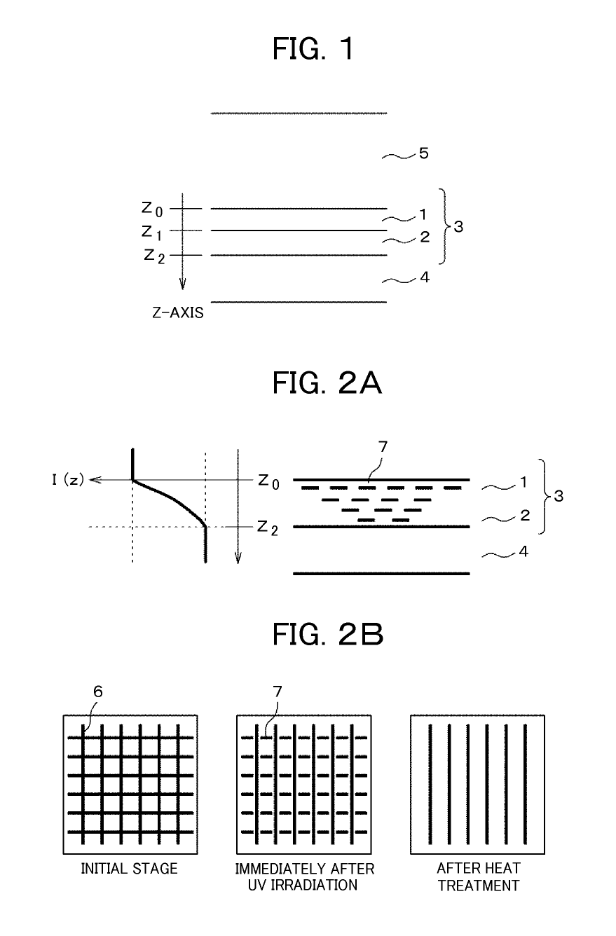

FIG. 1 is a schematic diagram of the basic configuration of a photo-alignment film of a liquid crystal display device according to an embodiment of the present invention. In the liquid crystal display device according to the embodiment of the present invention, a photo-alignment film 3 is formed on a base layer 4, and a liquid crystal layer 5 is formed on the base layer 4. Although not illustrated specifically, a counter substrate is mounted on which an alignment film in a similar configuration is provided. A liquid crystal alignment regulating force layer 1 is formed on the surface of the photo-alignment film 3 on the liquid crystal layer side, and a low optical anisotropy layer 2 is formed below the liquid crystal alignment regulating force layer 1. Here, it is supposed that a film thickness direction is defined as a Z-direction, the topmost position of the alignment film contacting the liquid crystal layer is defined as z₀, the lower end position of the layer 1 is defined as z₁, and the lower end of the layer 2 below the layer 1 is defined as z₂. In the embodiment of the present invention, the photo-alignment film 3 having two layers of different characteristics is formed of an alignment film material having the same composition.

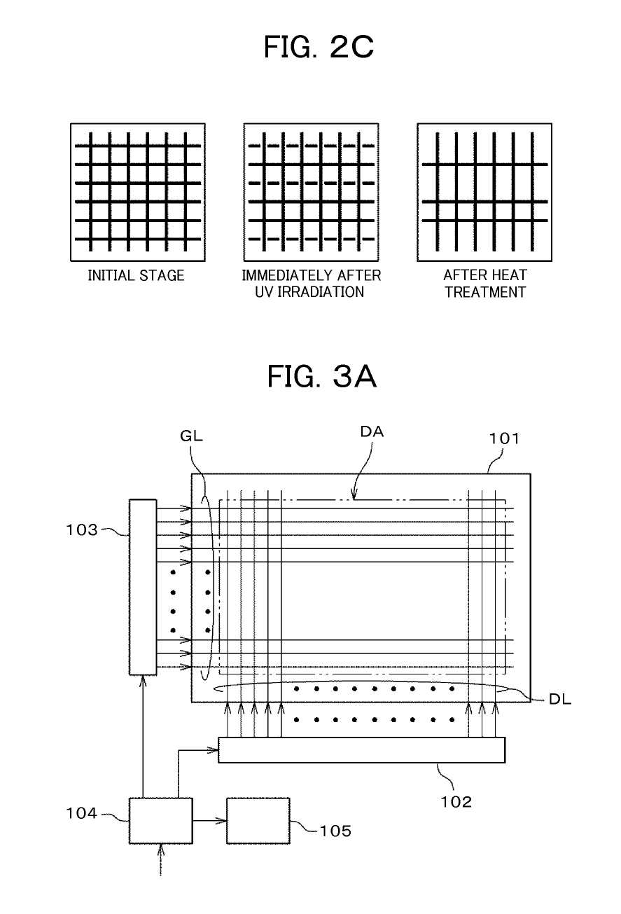

FIGS. 2A to 2C are schematic comparison of processes of providing alignment on the photo-alignment film according to the embodiment of the present invention. In order to implement liquid crystal alignment regulating force and low optical anisotropy in a single photo-alignment film, it is also possible to form the liquid crystal alignment regulating force layer 1 that reacts with polarized ultraviolet rays and the low optical anisotropy layer 2 that does not react with polarized ultraviolet rays using different materials. However, the film thickness of a typical photo-alignment film is around 100 nm, and there are problems in that it is necessary to more thinly coat the liquid crystal alignment regulating force layer 1 specifically and it is necessary to perform printing twice because two types of materials are necessary, for example.

When it is desired to achieve these two characteristics using one kind of material, the following method is available. As illustrated in FIG. 2A, although the intensity I(z) of ultraviolet rays to be applied is constant immediately before the rays are entered to the alignment film 3, the rays are exponentially attenuated after entered, and become constant after passed through the film. Thus, the photodecomposition of polymers in the alignment film proceeds quickly on the surface of the film, whereas photodecomposition proceeds more slowly in a direction deeper from the surface of the film. FIGS. 2B and 2C are schematic diagrams of the differences of optical cutting amounts on the surface of the film and in the inside of the film. First, when the surface of the film is considered, in the initial stage, it is supposed that polymers before photodecomposition (here, referred to as undecomposed polymers 6) are present in a matrix mesh form for simplicity.

When polarized ultraviolet rays are applied to the polymers in the lateral direction, the undecomposed polymers 6 in the lateral direction are photodecomposed in priority, and changed into decomposed polymers 7. (Actually, because polarized ultraviolet rays also include a small amount of ultraviolet components in the direction perpendicular to the polarization direction, the undecomposed polymers 6 in the vertical direction are gradually photodecomposed with application for sufficiently long hours. However, this photodecomposition is ignored for convenience.) The state of the optimum conditions for the appellation of polarized ultraviolet rays is a state in which the undecomposed polymers 6 on the surface in the lateral direction are just decomposed and only the undecomposed polymers 6 in the vertical direction are left. In this state, because a large number of the decomposed polymers 7 are left, anisotropy on the surface of the film is hardly observed, and liquid crystal alignment regulating force is also small.

When heat treatment is applied to the polymers, only the undecomposed polymers in the vertical direction are left as long as 100% of the decomposed polymers 7 in the lateral direction is ideally evaporated, anisotropy is produced on the surface of the film, and the liquid crystal alignment regulating force is at the maximum. (Actually, there are some photolytes having a moderate molecular weight and difficult to be evaporated in the atmosphere, and the photolytes are left in the film. However, the photolytes are ignored here.) In the processes, the state of polymers is observed at a certain depth in the inside of the film at a cross sectional position in parallel with the surface of the film. In the initial state, it is of course the same that there is the mesh structure of the undecomposed polymers 6 in a matrix form. When the state in the inside of the film is considered in the application of the optimum polarized ultraviolet rays to the surface, the state is a state in which the decomposed polymers 7 and the undecomposed polymers 6 are mixed in the lateral direction.

Although a great anisotropy is not produced also in the inside of the film in this state, after heat treatment is applied, the decomposed polymers 7 in the inside of the film are evaporated together with the evaporation of the decomposed polymers 7 on the surface of the film, and a certain anisotropy is produced also in the inside of the film, not the same as anisotropy on the surface. Since this anisotropy is piled up entirely in the film thickness direction, optical anisotropy is produced entirely in previously existing alignment films. This optical anisotropy causes retardation, and is a cause of the leakage of remaining light, for example. The embodiment of the present invention is to provide a photo-alignment film that removes photolytes only on the surface with no influence on photodecomposed polymers in the inside of the film, generates high anisotropy and high liquid crystal alignment regulating force on the surface, and does not generate anisotropy in the inside of the film.

More specifically, the photodecomposed polymers on the surface of the alignment film after the photo-alignment process are completely removed to the outside of the film in an atmosphere or by a solvent process that works only on the topmost surface without disturbing the molecular orientation of the remaining undecomposed polymers that are not photodecomposed. The photodecomposed polymers in the inside of the film are prevented from being diffused from the surface of the film to the outside of the film because the surface of the alignment film also serves as a coating layer to prevent the diffusion of the polymers. Alternatively, the photodecomposed polymers in the inside of the film are fixed by chemically bonding the remaining photodecomposed polymers after the decomposed polymers on the surface of the film are removed.

Such an ultrathin film can be formed by applying a moderate oxidation process to the surface of the alignment film after the photo-alignment process, for example. Changes in the element composition can be analyzed using various analysis methods for thin film surfaces including X-ray photoelectron spectroscopy (XPS), Auger electron spectroscopy, and a time-of-flight secondary mass spectrometer (TOF-SIMS), for example. First, the liquid crystal panel of a liquid crystal display device to be a target is disassembled, liquid crystals are cleaned using an alkane solvent such as cyclohexane, and dried to form a sample, and the sample is used for analysis in various manners. More specifically, in order to analyze the sample in the depth direction in the film thickness direction, the sample can be evaluated in which analysis is performed in various manners as the sample is sputtered using gas ions such as Ar.

In order to form such an ultrathin film on the surface of the alignment film, the ultrathin film can be prepared by the following procedures. In other words, a polyimide precursor capable of photo-alignment is coated over a base layer, a polyimide thin film is formed by heating, and polarized ultraviolet rays are applied to the surface of the thin film to provide alignment regulating force. The surface of the thin film is exposed to an oxidizing atmosphere before, during, or after the appellation of the polarized ultraviolet rays, and a layer having a high oxygen atom ratio is formed from the surface to the inside of the thin film.

For the method of the oxidation process, an ozone gas from air using an ultraviolet light source and various oxidizers (such as a hydrogen peroxide solution, hypochlorous acid solution, ozone water, hypoiodous acid solution, and permanganic acid solution) are used. In the oxidation process, how the distribution of the oxygen atom ratio is changed from the surface to the inside of the thin film is varied depending on an oxidizing atmosphere for use and exposure conditions. Moreover, in addition to polarized ultraviolet irradiation and exposure to an oxidizing atmosphere, it is also possible to apply heating, drying, and light at different wavelengths including infrared rays before, after, or during irradiation and exposure. Alternatively, it is also possible to apply processes using various solvents including water to remove foreign substances and the like on the surface before or after irradiation and exposure.

What ratio a layer having an increased oxygen atom ratio is formed on the surface of the photo-alignment film is desirably a ratio at which the liquid crystal alignment regulating force is not decreased by the photo-alignment process. More specifically, the thickness of the layer is desirably a half of the film thickness of the alignment film layer capable of photo-alignment from the surface contacting the liquid crystal, more desirably one-tenth of the film thickness or less, and still more desirably one-twentieth of the film thickness. The formation of a layer having an increased oxygen atom ratio limitedly on the surface of the photo-alignment film suppresses a harmful effect that the oxygen atom ratio is increased over these desirable ratios and the surface of the alignment film is excessively oxidized. For example, the following is suppressed. The surface of the alignment film is changed to have a hydrophilic property, the contact angle to water is decreased at an angle of 20 degrees or more, and the interaction between the alignment film and liquid crystal molecules is changed.

On the other hand, although the mechanism of occurrence is not yet determined, it is possible to improve the holding properties of the liquid crystal alignment regulating force by photo-alignment. For example, although the same liquid crystal alignment regulating force is provided immediately after a liquid crystal display device is formed, it is possible to shorten afterglow time in which the liquid crystal layer is continuously aligned in a direction different from the alignment direction of the liquid crystal induced by the liquid crystal alignment regulating force for a long time using an electric field and the alignment direction is returned to the initial alignment direction after the electric field is removed.

Moreover, in the preparation of the alignment film according to the embodiment of the present invention, two kinds or more of alignment films are coated and imidized in layers, or two kinds or more of polyimide precursors are blended, coated, and imidized, and the composition can be adjusted. The alignment films after subjected to these processes can be assembled on a liquid crystal display device by typical methods.

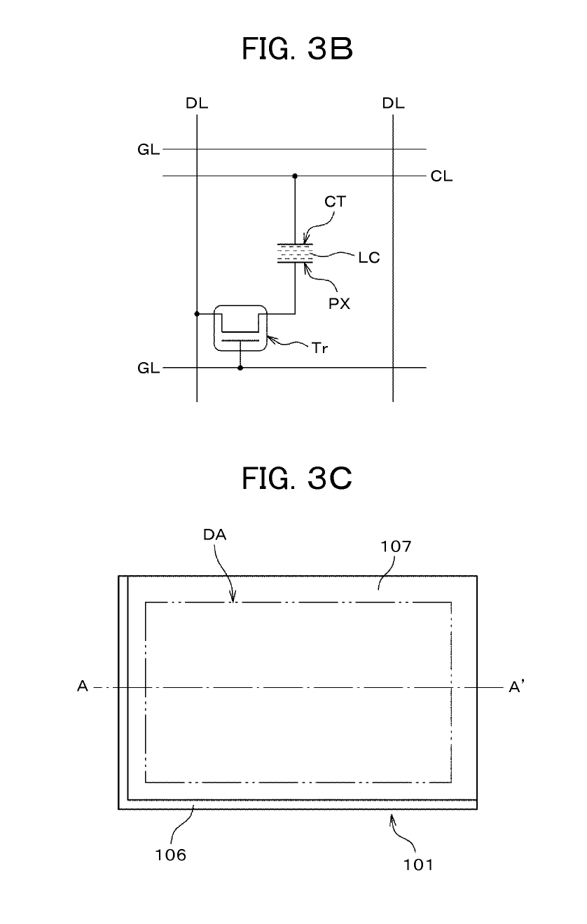

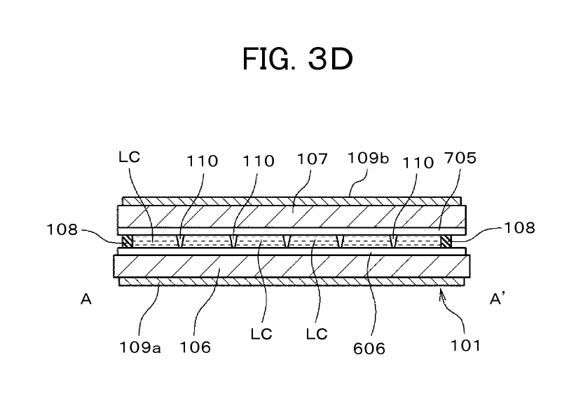

Next, a liquid crystal display device on which the alignment film is prepared will be described. FIGS. 3A to 3D are a schematic diagram of an exemplary schematic configuration of a liquid crystal display device according to the embodiment of the present invention. FIG. 3A is a schematic block diagram of an exemplary schematic configuration of the liquid crystal display device. FIG. 3B is a schematic circuit diagram of an exemplary circuit configuration of a single pixel of a liquid crystal display panel. FIG. 3C is a schematic plan view of an exemplary schematic configuration of the liquid crystal display panel. FIG. 3D is a cross sectional view of an exemplary cross sectional configuration taken along line A-A′ in FIG. 3C.

The alignment film, which an oxygen atom ratio is increased on the surface as the hydrophobic state is maintained, is adapted to an active matrix liquid crystal display device, for example. The active matrix liquid crystal display device is used for a display (a monitor) intended for a mobile electronic device, a display for a personal computer, a display intended for printing and design, a display for a medical device, and a liquid crystal television, for example.

As illustrated in FIG. 3A, the active matrix liquid crystal display device has, for example, a liquid crystal display panel 101, a first drive circuit 102, a second drive circuit 103, a control circuit 104, and a backlight 105.

The liquid crystal display panel 101 has a plurality of scanning signal lines GL (gate lines) and a plurality of picture signal lines DL (drain lines). The picture signal line DL is connected to the first drive circuit 102, and the scanning signal line GL is connected to the second drive circuit 103. It is noted that in FIG. 3A, a plurality of the scanning signal lines GL is partially illustrated, and on the actual liquid crystal display panel 101, a larger number of the scanning signal lines GL are closely disposed. Similarly, in FIG. 3A, a plurality of the picture signal lines DL is partially illustrated, and on the actual liquid crystal display panel 101, a larger number of the picture signal line DL are closely disposed.

Moreover, a display region DA of the liquid crystal display panel 101 is configured of a group of a large number of pixels. A region occupied by a single pixel on the display region DA corresponds to a region surrounded by two adjacent scanning signal lines GL and two adjacent picture signal lines DL, for example. In this case, the circuit configuration of a single pixel is a configuration as illustrated in FIG. 3B, for example, and the pixel includes a TFT element Tr that functions as an active element, a pixel electrode PX, a common electrode CT (sometimes referred to as a counter electrode), and a liquid crystal layer LC. Furthermore, in this case, the liquid crystal display panel 101 is provided with a common interconnection CL that provides commonality of the common electrodes CT of a plurality of the pixels, for example.

In addition, as illustrated in FIGS. 3C and 3D, for example, the liquid crystal display panel 101 has a structure in which alignment films 606 and 705 are formed on the surfaces of an active matrix substrate (a TFT substrate) 106 and a counter substrate 107, respectively, and the liquid crystal layer LC (a liquid crystal material) is disposed between the alignment films. Moreover, not specifically illustrated in the drawings here, it may be fine to appropriately provide an intermediate layer (an optical intermediate layer including a retardation plate, a color conversion layer, and a light diffusion layer, for example) between the alignment film 606 and the active matrix substrate 106 or between the alignment film 705 and the counter substrate 107.

In this case, the active matrix substrate 106 is attached to the counter substrate 107 with an annular sealing material 108 provided on the outer side of the display region DA, and the liquid crystal layer LC is encapsulated in a space surrounded by the alignment film 606 on the active matrix substrate 106 side, the alignment film 705 on the counter substrate 107 side, and the sealing material 108. Furthermore, in this case, the liquid crystal display panel 101 of the liquid crystal display device having the backlight 105 includes a pair of polarizers 109a and 109b opposedly disposed as the active matrix substrate 106, the liquid crystal layer LC, and the counter substrate 107 are sandwiched.

It is noted that the active matrix substrate 106 is a substrate on which the scanning signal lines GL, the picture signal lines DL, the active elements (the TFT elements Tr), the pixel electrodes PX, and the like are disposed on an insulating substrate such as a glass substrate. Moreover, in the case where the driving method for the liquid crystal display panel 101 is a transverse electric field drive mode such as the IPS mode, the common electrode CT and the common interconnection CL are disposed on the active matrix substrate 106. Furthermore, in the case where the driving method for the liquid crystal display panel 101 is a vertical electric field drive mode such as the TN mode and the VA (Vertical Alignment) mode, the common electrode CT is disposed on the counter substrate 107. In the case of the liquid crystal display panel 101 in the vertical electric field drive mode, the common electrode CT is typically a large area plate electrode shared by all the pixels, and the common interconnection CL is not provided.

Furthermore, in the liquid crystal display device according to the embodiment of the present invention, a plurality of columnar spacers 110 is provided in the space, in which the liquid crystal layer LC is encapsulated, to uniformize the thickness of the liquid crystal layer LC (sometimes referred to as a cell gap) in the pixels, for example. The plurality of the columnar spacers 110 is provided on the counter substrate 107, for example.

The first drive circuit 102 is a drive circuit that generates a picture signal (sometimes referred to as a gray scale voltage) applied to the pixel electrodes PX of the pixels through the picture signal lines DL, and is a drive circuit generally called a source driver and a data drive, for example. Moreover, the second drive circuit 103 is a drive circuit that generates scanning signals applied to the scanning signal lines GL, and is a drive circuit generally called a gate driver and a scan driver, for example. Furthermore, the control circuit 104 is a circuit that controls the operation of the first drive circuit 102, the operation of the second drive circuit 103, and the brightness of the backlight 105, for example, and is a control circuit generally called a TFT controller and a timing controller, for example. In addition, the backlight 105 is a fluorescent lamp including a cold cathode fluorescent lamp or a light source including a light emitting diode (LED), for example. Light emitted from the backlight 105 is converted into planar rays through a reflector, a light guide plate, a light diffuser, a prism sheet, and the like, not illustrated, and applied to the liquid crystal display panel 101.

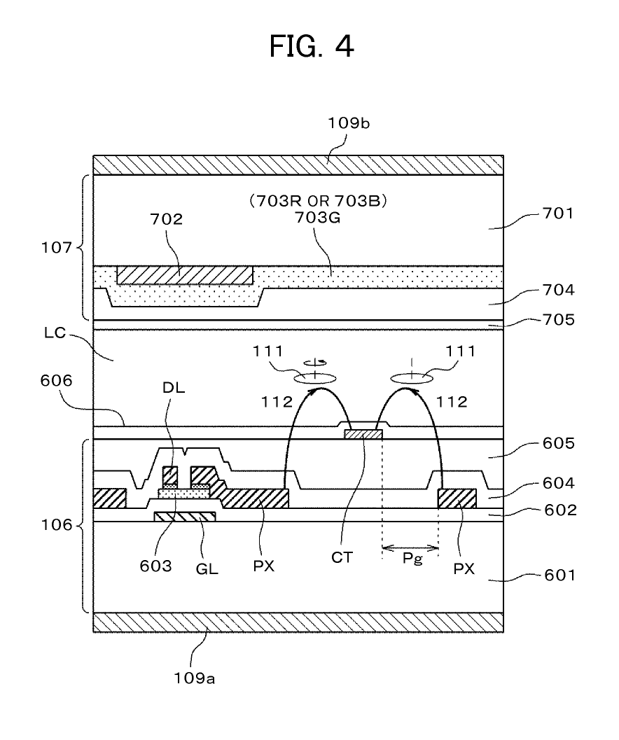

FIG. 4 is a schematic diagram of an exemplary schematic configuration of an IPS mode liquid crystal display panel of the liquid crystal display device according to the embodiment of the present invention. An active matrix substrate 106 includes a scanning signal line GL, a common interconnection CL not illustrated in FIG. 4, and a first insulating layer 602 that covers these components formed on the surface of an insulating substrate such as a glass substrate 601. On the first insulating layer 602, a semiconductor layer 603 of a TFT element Tr, a picture signal line DL, a pixel electrode PX, and a second insulating layer 604 that covers these components are formed. The semiconductor layer 603 is disposed on the scanning signal line GL, and the portion of the scanning signal line GL located on the lower part of the semiconductor layer 603 functions as the gate electrode of the TFT element Tr.

Moreover, the semiconductor layer 603 is in a configuration in which, for example, an active layer (a channel forming layer) is formed of first amorphous silicon, and a source diffusion layer and a drain diffusion layer formed of second amorphous silicon having an impurity type and concentration different from the first amorphous silicon are stacked on the active layer. Furthermore, in this configuration, a part of the picture signal line DL and a part of the pixel electrode PX are on the semiconductor layer 603, and the portions on the semiconductor layer 603 function as the drain electrode and source electrode of the TFT element Tr.

The source and drain of the TFT element Tr are switched to each other depending on the relationship of biases, that is, the relationship between the levels of the potential of the pixel electrode PX and the potential of the picture signal line DL when the TFT element Tr is turned on. However, in the following description of the present specification, the electrode connected to the picture signal line DL is referred to as a drain electrode, and the electrode connected to the pixel electrode is referred to as a source electrode. On the second insulating layer 604, a third insulating layer 605 (an organic passivation film) whose surface is planarized is formed. On the third insulating layer 605, a common electrode CT and an alignment film 606 that covers the common electrode CT and the third insulating layer 605 are formed.

The common electrode CT is connected to the common interconnection CL through a contact hole (a through hole) that penetrates the first insulating layer 602, the second insulating layer 604, and the third insulating layer 605. Moreover, the common electrode CT is formed in such a manner that a gap Pg to the pixel electrode PX on a plane is about 7 μm, for example. The alignment film 606 is coated with a polymeric material described in embodiments below, the surface is subjected to surface treatment (a photo-alignment process) and an oxidation process for providing the liquid crystal aligning function, and the oxygen atom ratio on the surface of the alignment film is improved in the state in which the hydrophobic property is maintained.

On the other hand, a counter substrate 107 is formed with a black matrix 702 and color filters (703R, 703G, and 703B), and an overcoat layer 704 that covers these components on the surface of an insulating substrate such as a glass substrate 701. The black matrix 702 is a grid-like light shielding film for providing opening regions on a display region DA in units of the pixels, for example. Moreover, the color filters (703R, 703G, and 703B) are films that transmit only certain rays in specific wavelength regions (colors) in white light emitted from a backlight 105, for example. In the case where the liquid crystal display device is adapted to color display in the RGB mode, these color filters are disposed: the color filter 703R that transmits red light; the color filter 703G that transmits green light; and the color filter 703B that transmits blue light. Here, the pixel in one color is illustrated for a representing one.

Moreover, the surface of the overcoat layer 704 is planarized. On the overcoat layer 704, a plurality of columnar spacers 110 and an alignment film 705 are formed. The columnar spacer 110 is a circular truncated cone with a flat topmost (sometimes referred to as a trapezoid rotator), for example, and is formed at a position on the scanning signal line GL of the active matrix substrate 106 except a portion at which the TFT element Tr is disposed and a portion at which the picture signal line DL is crossed. Furthermore, the alignment film 705 is formed of a polyimide based resin, for example. The surface is subjected to surface treatment (a photo-alignment process) and an oxidation process for providing the liquid crystal aligning function, and the oxygen atom ratio on the surface of the alignment film is improved in the state in which the hydrophobic property is maintained.

In addition, liquid crystal molecules 111 in a liquid crystal layer LC of a liquid crystal display panel 101 in the mode in FIG. 4 are in the state in which the liquid crystal molecules 111 are aligned nearly in parallel with the surfaces of the glass substrates 601 and 701 when an electric field that the potentials of the pixel electrode PX and the common electrode CT are equal is not applied, and the liquid crystal molecules 111 are in homogeneous alignment in the state in which the liquid crystal molecules 111 are oriented to the initial alignment direction defined by the alignment regulating force process applied to the alignment films 606 and 705. When the TFT element Tr is turned on, a gray scale voltage applied to the picture signal line DL is written to the pixel electrode PX, and then a potential difference is produced between the pixel electrode PX and the common electrode CT, an electric field 112 (an electric flux line) illustrated in FIG. 4 is produced, and the electric field 112 whose strength corresponds to the potential difference between the pixel electrode PX and the common electrode CT is applied to the liquid crystal molecules 111.

In the application, the interaction between dielectric anisotropy of the liquid crystal layer LC and the electric field 112 changes the orientations of the liquid crystal molecules 111 forming the liquid crystal layer LC in the direction of the electric field 112, and the refractive anisotropy of the liquid crystal layer LC is changed. Moreover, in the application, the orientations of the liquid crystal molecules 111 are determined by the strength of the electric field 112 to be applied (the size of the potential difference between the pixel electrode PX and the common electrode CT). Thus, in the liquid crystal display device, the potential of the common electrode CT is fixed, and the gray scale voltage applied to the pixel electrode PX is controlled for the individual pixels to change the transmittances of the pixels, so that pictures and image can be displayed, for example.

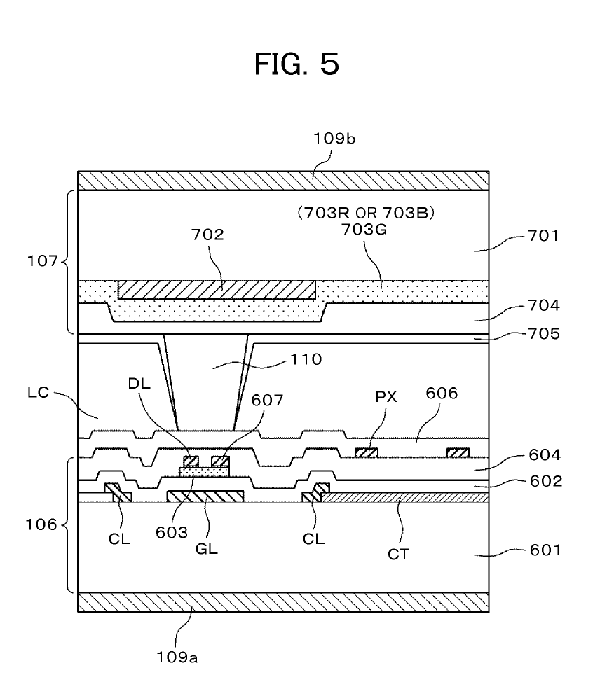

FIG. 5 is a schematic diagram of an exemplary schematic configuration of an FFS mode liquid crystal display panel of another liquid crystal display device according to the embodiment of the present invention. An active matrix substrate 106 is formed with a common electrode CT, a scanning signal line GL, a common interconnection CL, and a first insulating layer 602 that covers these components on the surface of an insulating substrate such as a glass substrate 601. On the first insulating layer 602, a semiconductor layer 603 of a TFT element Tr, a picture signal line DL, and a source electrode 607, and a second insulating layer 604 that covers these components are formed. In this case, a part of the picture signal line DL and a part of the source electrode 607 are on the semiconductor layer 603, and the portions on the semiconductor layer 603 function as the drain electrode and the source electrode of the TFT element Tr.

Moreover, in a liquid crystal display panel 101 in FIG. 5, the third insulating layer 605 is not formed, and a pixel electrode PX and an alignment film 606 that covers the pixel electrode PX are formed on the second insulating layer 604. Although not illustrated in FIG. 5, the pixel electrode PX is connected to the source electrode 607 through a contact hole (a through hole) that penetrates the second insulating layer 604. In this case, the common electrode CT formed on the surface of the glass substrate 601 is formed in a flat plate shape on a region (an opening region) surrounded by two adjacent scanning signal lines GL and two adjacent picture signal lines DL, and the pixel electrode PX having a plurality of slits is stacked on the common electrode CT in a flat plate shape. Furthermore, in this case, the common electrode CT of the pixels arranged in the extending direction of the scanning signal line GL is shared by the common interconnection CL. In contrast, a counter substrate 107 of the liquid crystal display panel 101 in FIG. 5 has the same configuration as the configuration of the counter substrate 107 of the liquid crystal display panel 101 in FIG. 4. Thus, the detailed description of the configuration of the counter substrate 107 is omitted.

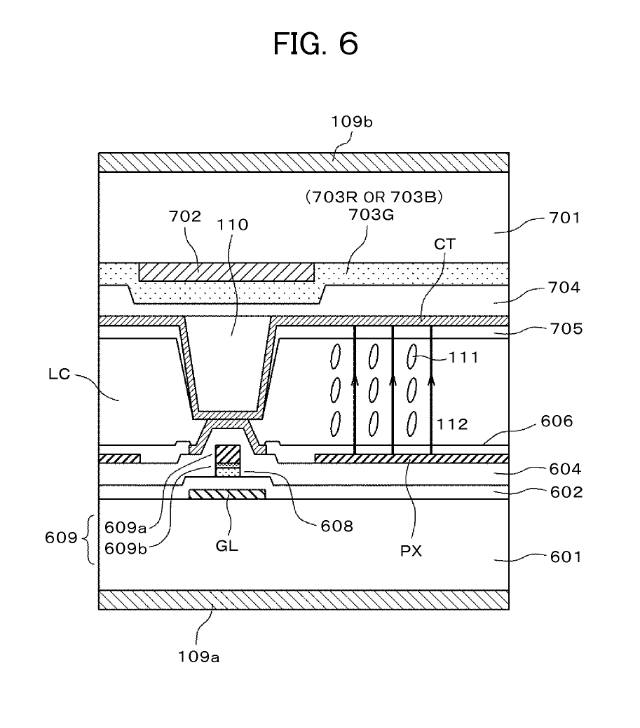

FIG. 6 is a cross sectional view of an exemplary cross sectional configuration of the main components of a VA mode liquid crystal display panel of still another liquid crystal display device according to the embodiment of the present invention. As illustrated in FIG. 6, in a liquid crystal display panel 101 in the vertical electric field drive mode, a pixel electrode PX is formed on an active matrix substrate 106, for example, and a common electrode CT is formed on a counter substrate 107. In the case of the VA mode liquid crystal display panel 101, which is one of vertical electric field drive modes, the pixel electrode PX and the common electrode CT are formed in a solidly filled shape (a simple flat shape) with a transparent conductor such as ITO.

In this case, liquid crystal molecules 111 are vertically aligned to the surfaces of the glass substrates 601 and 701 caused by alignment films 606 and 705 when an electric field that the potentials of the pixel electrode PX and the common electrode CT are equal is not applied. When a potential difference is produced between the pixel electrode PX and the common electrode CT, an electric field 112 (an electric flux line) almost perpendicular to the glass substrates 601 and 701 is produced, the liquid crystal molecules 111 are laid in the direction in parallel with the substrates 601 and 701, and the polarization state of incident light is changed. Moreover, in this case, the orientations of the liquid crystal molecules 111 are determined according to the strength of the electric field 112 to be applied.

Thus, in the liquid crystal display device, pictures and images are displayed in which for example, the potential of the common electrode CT is fixed and a picture signal (a gray scale voltage) applied to the pixel electrode PX is controlled for the individual pixels to change the transmittances of the pixels. Moreover, various configurations are known for the configuration of the pixel of the VA mode liquid crystal display panel 10, for the planner shape of the TFT element Tr and the pixel electrode PX, for example. It may be fine that the configuration of the pixel of the VA mode liquid crystal display panel 10 illustrated in FIG. 6 is any one of these configurations. Here, the detailed description of the configuration of the pixel of the liquid crystal display panel 101 is omitted. It is noted that a reference numeral 608 denotes a conductive layer, a reference numeral 609 denotes a projection forming member, a reference numeral 609a denotes a semiconductor layer, and a reference numeral 609b denotes a conductive layer.

The embodiment of the present invention relates to the liquid crystal display panel 101 in the active matrix liquid crystal display devices as decried above, and specifically to the configurations of the portions contacting the liquid crystal layer LC on the active matrix substrate 106 and the counter substrate 107 and components around the containing portions. Thus, the detailed description of the configurations of the first drive circuit 102, the second drive circuit 103, the control circuit 104, and the backlight 105, to which previously existing techniques can be applied as they are, is omitted.

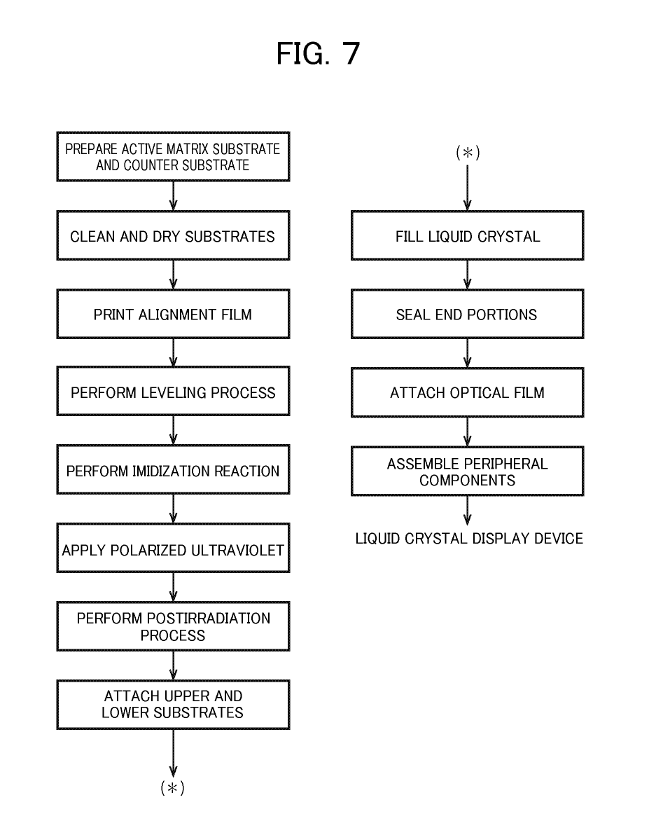

In order to manufacture these liquid crystal display devices, various alignment film materials, alignment methods, various liquid crystal materials, and the like, which are already used for liquid crystal display devices, can be used, and various processes for assembling and processing these materials can also be adapted. FIG. 7 is an example of processes. First, an active matrix substrate and a counter substrate are prepared through manufacture processes for the substrates, and the surfaces of base layers on which alignment films are formed are cleaned using various surface treatment methods such as a UV/ozone method, excimer UV method, and oxygen plasma method.

Subsequently, the precursor of the alignment film is coated using various printing methods such as screen printing, flexographic printing, and ink jet printing. The film is subjected to a leveling process to provide a uniform film thickness under predetermined conditions, and then the film is heated at a temperature of 180° C. or more, for example, to imidize a precursor polyamide to polyimide. Moreover, alignment regulating force is produced on the surface of the polyimide alignment film by applying polarized ultraviolet rays or by moderate postprocessing using desired schemes (photo-alignment). It is also possible to apply heating or light at another wavelength to the film in the stage of the polarized ultraviolet irradiation or the postirradiation process. Furthermore, in any one stage before or after the polarized ultraviolet irradiation, the surface treatment processes as described above are applied, and a photo-alignment film is formed that liquid crystal alignment regulating force on the surface is high and optical anisotropy is not observed on the entire film.

The active matrix substrate and the counter substrate attached with the alignment film thus formed are attached to each other with a certain gap maintained as the direction of the alignment regulating force is in the desired orientation. After that, the gap maintained is filled with a liquid crystal, the end portions of the substrates are sealed, and a liquid crystal panel is completed. To the panel, optical films such as a polarizer and a retardation plate are attached, a drive circuit, a backlight, and other components are mounted, and a liquid crystal display device is obtained. It is noted that in the description above, both of the alignment film formed on the active matrix substrate (the TFT substrate) and the alignment film formed on the counter substrate (the CF substrate) are exposed to an oxidizing atmosphere. However, even though any one of the alignment films is exposed, the effect of improving afterglow characteristics can be obtained. However, it is without saying that the alignment films are subjected to the surface treatment to further improve the afterglow characteristics.

Next, an exemplary confirming method will be described in which the obtained photo-alignment film is a film having desired characteristics and the liquid crystal display device obtained by mounting the film is a device having desired characteristics. First, the anchoring force of the liquid crystal that expresses the level of alignment regulating force can be measured by a method below. In other words, an alignment film is coated on a pair of two glass substrates, and subjected to the photo-alignment process. The alignment directions of these two the alignment films are in parallel with each other, spacers having a suited thickness d are disposed, and an evaluation homogeneous alignment liquid crystal cell is prepared. The cell is filled with a nematic liquid crystal material containing a chiral agent of known material properties (a helical pitch is p and an elastic constant is K₂). After the evaluation cell is temporarily held in an isotropic phase in order to stabilize the orientation, the temperature is returned to an ambient temperature, and then a twist angle φ₂ is measured by a method below.

Subsequently, most of the liquid crystal in the cell is removed using the pressure of air or centrifugal force, and the inside of the cell is cleaned using a solvent and then dried. The cell is filled with a nematic liquid crystal material containing the same liquid crystal and not containing a chiral agent, the orientation is similarly stabilized, and then a twist angle φ₁ is measured. In the measurement, the anchoring strength is given by Equation 1. It is noted that in Equation 1, K₂ is the elastic coefficient of liquid crystal in use.

$${A}_{φ} = \frac{2 {K}_{2} ( 2 π d / p - {φ}_{2} )}{d sin ( {φ}_{2} - {φ}_{1} )} \qquad ( Equation 1 )$$

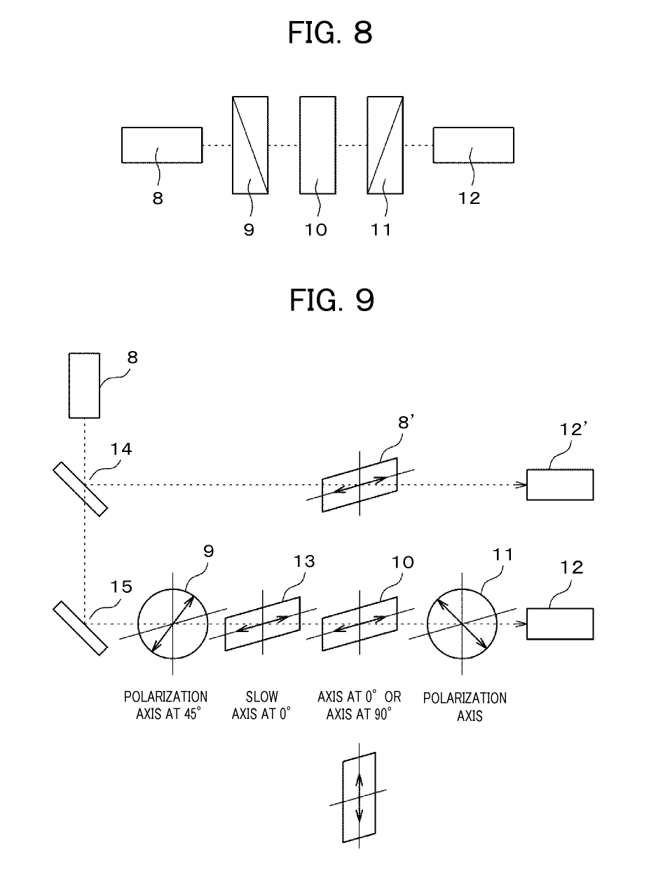

Moreover, the twist angles were measured using an optical system as illustrated in FIG. 8. In other words, a visible light source 8 and a photomultiplier tube 12 are collimated on the same straight line, and a polarizer 9, an evaluation cell 10, and an analyzer 11 are disposed in this order between the visible light source 8 and the photomultiplier tube 12. A tungsten lamp is used for the visible light source 8. First, the transmission axis of the polarizer 9 and the absorption axis of the analyzer 11 are disposed nearly in parallel with the alignment directions of the alignment films of the evaluation cell 10. Subsequently, only the polarizer is rotated, and the angle is changed in such a manner that the intensity of transmitted light becomes the smallest. Subsequently, only the analyzer is rotated, and the angle is changed in such a manner that the intensity of transmitted light becomes the smallest.

The rotation of only the polarizer and the rotation of only the analyzer are similarly repeated, and the rotations are repeated until angles become constant. For a transmission axis rotation angle φ_{polarizer} and an absorption axis rotation angle φ_{analyzer} at a point in time when convergence is finally achieved are defined as

twist angle φ=angle φ_{analyzer}−angle φ_{polarizer}.

Here, measurement errors can be decreased by adjusting a refractive index anisotropy Δn of the liquid crystal and the thickness d of the liquid crystal cell for use.

Next, a measurement method of retardation will be described. FIG. 9 is an illustration of an alignment film micro birefringence measurement system that measures retardation in the embodiment of the present invention. The system is configured in which light at a single wavelength emitted from a light source is passed through an incident side polarizer disposed nearly orthogonal to the optical axis, a retardation plate, a measurement sample, and a transmission side polarizer, and then entered to a photodetector. A commercially available spectrophotometer can be used for the light source and the photodetector. In the embodiment, a double beam spectrophotometer, Model U-3310 manufactured by Hitachi, Ltd., (a wavelength slit width of 2 nm) was used. Two measurement samples were taken from adjacent places on a substrate SUB1 and on a substrate SUB2.

The micro birefringence optical system was disposed on the sample side of the spectrophotometer, and only another measurement sample in the same specifications was disposed on the reference side. For the polarizer, a polarizer having a high degree of polarization is necessary, and for the retardation plate, a retardation plate having a small wavelength dispersion is desirable. In the embodiment, for the polarizer, a polarizer, SEG1425DU manufactured by Nitto Denko Corporation, was used, and for the retardation plate, a retardation plate was used that ARTON film (a half-wave plate) manufactured by JSR Corporation was attached to glass, Corning 7059 manufactured by Corning Incorporated. The polarization axis of the incident side polarizer and the polarization axis of the transmission side polarizer are disposed to be nearly orthogonal to each other (angles of 45° and 135° in FIG. 9), and the retardation plate is disposed at an angle of about 45° to the incident side polarization axis and the transmission side polarization axis (an angle of 0° in FIG. 9).

The measurement sample was mounted on a stage freely rotatable on a plane perpendicular to the optical axis on the optical path (a rotary stage manufactured by Sigmakoki Co., Ltd., for example). The measurement sample was disposed in such a manner that the alignment axis was at angle of about 0° to the retardation plate, and spectral transmittances were measured in a wavelength range of 400 to 700 nm in one nanometer steps. Moreover, the measurement sample was disposed in such a manner that the alignment axis was at angle of about 90° to the retardation plate, and spectral transmittances were similarly measured in a wavelength range of 400 to 700 nm in one nanometer steps. Wavelengths were found at which the spectral transmittance was at the minimum for these cases. In the following, a method of determining the retardation of a measurement substrate will be described at the wavelength at which the spectral transmittance is at the minimum when the measurement sample is disposed in the direction at angle of 0° to the retardation plate and the wavelength at which the spectral transmittance is at the minimum when the measurement sample is disposed in the direction at angle of 90° to the retardation plate; the wavelengths were measured using the micro birefringence measurement system.

In the case where a uni-axial thin film whose optical axis is in parallel with the Y-axis is sandwiched between two polarizers, the intensity of transmitted light is expressed by Equation 2.

I=I₀[ cos² φ−sin 2φ sin 2(φ−φ)sin² ε/2] (Equation 2)

Where I₀ is the incident light intensity, d is the film thickness, π is the circular constant, and λ is the wavelength of measured light, δ=2πΔn·d/λ.

As illustrated in FIG. 9, the polarizers are disposed in such a manner that the polarization axes of the upper and lower polarizers are orthogonal to each other and the polarization axes are at an angle 45° to the optical axis, and then Ψ=90° and φ=45°. Equation 2 is simplified as Equation 3.

I=I₀ sin²(πΔn·d/λ) (Equation 3)

The intensity of transmitted light is at the minimum, in the case where the conditions of Equation 4 are held.

πΔn·d/λ=m (m=0, 1, 2, . . . ) (Equation 4)

Using the relationship in Equation 4, Δnd is found from the measurement of a minimum transmittance wavelength (λmin). For the retardation plate used in the embodiment of the present invention, a retardation plate that takes the third-order minimum (m=3) near a wavelength of 550 nm was used, and then Equation 4 becomes Equation 5.

πΔn·d/λ=3 (Equation 5)

The composite phase difference of the retardation plate using two uni-axial films is given by the sum of the films in the case where the films are stacked as the optical axes are in parallel with each other, and the composite phase difference is given by a difference in the case where the films are stacked as the optical axes are orthogonal to each other. Here, suppose that Δnd of the retardation plate is defined as R, and the retardation of the measurement substrate is defined as r. Suppose that the minimum transmittance wavelength is defined as λₚ in the case where the alignment direction of the measurement substrate is in parallel with the optical axis of the retardation plate, and the minimum transmittance wavelength is defined as λ_{T} in the case where the alignment direction is orthogonal to the optical axis of the retardation plate, and then Equation 6 and Equation 7 below are obtained from Equation 5.

R+r=3λₚ (Equation 6)

R−r=3λ_{T} (Equation 7)

Equation 7 is subtracted from Equation 6, and then Equation 8 is obtained.

r=3(λₚ−λ_{T})/2 (Equation 8)

In other words, λₚ and λ_{T} are measured using the spectrophotometer, and then a retardation r of the measurement substrate is found from Equation 8. It is noted that strictly speaking, Equation 8 is incorrect because R and r have wavelength dependence. However, in the measurement of micro phase differences, the values of λₚ and λ_{T} are close (about 50 nm even in a large difference), and the ARTON film of a small wavelength dispersion is used for the retardation plate. Thus, it is almost unnecessary to consider the wavelength dependence of retardation at a wavelength difference of about 50 nm, and Equation 8 is applicable.

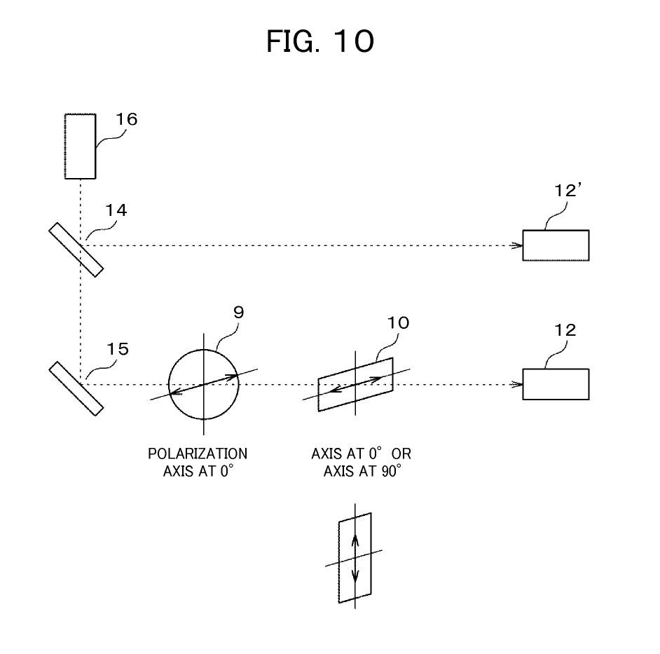

Next, an exemplary measurement method for the absorption anisotropy of the alignment film in film surface will be described as another evaluation method for optical anisotropy. FIG. 10 is an exemplary measurement system for the polarized ultraviolet visible absorption spectrum of the obtained photo-alignment film. A light beam emitted from an ultraviolet visible spectroscopic light source 16 is split into two optical paths at a beam splitter 14. One light beam is guided to a photomultiplier tube 12′ as a reference beam unchanged, and the light quantity of the ultraviolet visible spectroscopic light source 16 is measured. A light beam on another optical path is reflected at a mirror 15, changed to a linear polarized light beam at a polarizer 9, passed through a sample 10, and then guided to another photomultiplier tube 12, and the transmitted light quantity is measured.

The quantities of transmitted light beams on two optical paths are measured in advance in the state in which the sample 10 is not set, and the transmittance or the absorbance can be found from the ratios to the light quantities when the sample 10 is measured. Although not specifically illustrated here, the sample is fixed to a holder freely rotatable on a plane perpendicular to the optical path. In the case where an alignment film that is not subjected to the photo-alignment process is used for a sample, the alignment film has no optical anisotropy. Thus, even though the rotation angle of the holder is changed, the transmitted light quantity is constant, whereas the alignment film has optical anisotropy caused by the photo-alignment process and the like, the transmitted light quantity is changed depending on the rotation angle of the holder. Suppose that the polarization axis of the polarizer is at an angle of 0°, the absorbance of the transmitted light beam exhibits the maximum or minimum absorbance when the rotation angle of the sample holder is at an angle of 0° at which the holder is in parallel with the polarizer and when the rotation angle is at an angle of 90° at which the holder is perpendicular to the polarizer.

In many cases, the direction in which the absorbance is at the minimum is the case where the rotation angle is in parallel with the irradiation angle of polarized ultraviolet rays in the photo-alignment process, whereas the direction in which the absorbance is at the maximum is the case where the rotation angle is perpendicular to the irradiation angle of polarized ultraviolet rays. A dichroic ratio D that expresses the optical anisotropy of the sample is expressed by Equation 9, where the maximum absorbance is Aₘₐₓ and the minimum absorbance is Aₘᵢₙ.

$$D = \frac{{A}_{max} - {A}_{min}}{{A}_{max} + {A}_{min}} \qquad ( Equation 9 )$$

Alternatively, an order parameter S is expressed by

Equation 10.

$$S = \frac{{A}_{max} - {A}_{min}}{{A}_{max} + 2 {A}_{min}} = \frac{D - 1}{D + 2} \qquad ( Equation 10 )$$

For example, as in embodiments described later, in the case of polyimide having a phenylene ring and a cyclobutane ring in the polymer main chain, the characteristic optical absorption corresponding to the π−π* absorption of the phenylene ring is observed around at a wavelength of 220 to 300 nm. In the wavelength range, the dichroic ratio or the order parameter at the wavelength at which the absorption is at the maximum is categorized as the dichroic ratio or the order parameter of the sample thin film. As described above, when the absorption spectrum of the film alone can be measured, the order parameter can be found from the anisotropy of the absorbance.

Next, a luminance relaxation constant can be measured by a method below. Various liquid crystal display devices including the alignment films are prepared by the procedures as described in detail above. A black-and-white window pattern is continuously displayed on the liquid crystal display devices for a predetermined period (this is referred to as screen burn time), the voltage is immediately switched to a gray level display voltage that the entire screen is in a halftone, and the time for which the window pattern (also referred to as burn-in or afterglow) disappears is measured.

Ideally in the alignment film, because residual electric charges are not produced in any portions of the liquid crystal display device and the direction of the alignment regulating force is not disturbed as well, the gray level display is shown on the entire screen immediately after switching the display voltage. However, the effective orientation state is shifted from the ideal level in bright regions (white pattern portions) caused by the production of residual electric charges and the disturbance of the direction of the alignment regulating force, for example, in association with driving, and brightness is viewed differently. After the halftone display voltage is further maintained for a long time, residual electric charges and the direction of the alignment regulating force become stable at this voltage, and then uniform display is observed. The in-plane luminance distribution of the liquid crystal display device was measured using a CCD camera, a period until which uniform display was observed was defined as burn-in time, and the burn-in time is defined as the luminance relaxation constant of the liquid crystal display device. However, in the case where the display was not relaxed after a lapse of 480 hours, evaluation was stopped, and the notation 480 was written.

In the following, the present invention will be described in more detail with reference to embodiments.

The technical scope of the present invention will not limited to the embodiments below.

### First Embodiment

First, a result of preparing a liquid crystal display device will be described with reference to the drawings and tables, the liquid crystal display device including: a TFT substrate having a pixel electrode and a TFT and formed with an alignment film on a pixel; a counter substrate disposed opposite to the TFT substrate and formed with an alignment film on a topmost surface on the TFT substrate side; and a liquid crystal sandwiched between the alignment film of the TFT substrate and the alignment film of the counter substrate. In the liquid crystal display device, the alignment film is a material that is enabled to provide liquid crystal alignment regulating force by applying polarized light. The topmost surface layer of the photo-alignment film has liquid crystal alignment regulating force, and the photo-alignment film has little optical anisotropy.

Three types of substrates were used in which fused silica and no alkaline glass (AN-100 manufactured by Asahi Glass Co., Ltd) were used for the substrates, and oxidation indium tin (ITO) thin film was formed on the glass by sputtering. The base substrates thus prepared were cleaned with a chemical solution such as a neutral detergent prior to coating the precursor of the alignment film, and the surfaces were purified by UV/O₃ processing. Alignment films below were used for test alignment films. For the framework of polyamic acid to be a polyimide precursor in Chemical formula 2, a chemical structure expressed by Chemical formula 3 was selected for the component of a first alignment film, and polyamic acid to be a raw material was composed from acid dianhydride and diamine according to an existing chemical synthesis method.

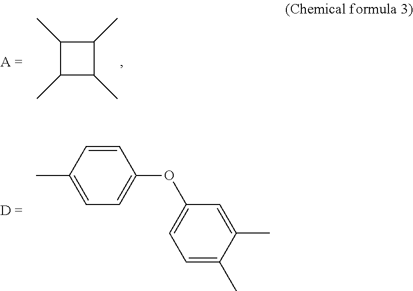

Moreover, for the component of a second alignment film, a structure expressed by Chemical formula 4 was selected.

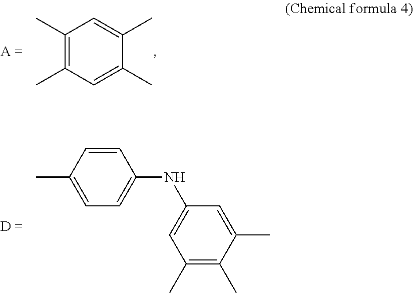

The molecular weights of these polyamic acids were found from polystyrene-converted molecular weights by gel permeation chromatography (GPC) analysis, and were 16,000 and 14,000, respectively. The polyamic acids were dissolved in a mixture of various solvents such as butyl cellosolve, N-methylpyrrolidone, and γ-butyrolactone at a ratio, the first alignment film:the second alignment film=1:1. A thin film was formed by coating the solution on a predetermined base substrate by flexographic printing, temporarily dried at a temperature of 40° C. or more, and imidized in a baking furnace at a temperature of 150° C. or more. The conditions for forming the thin film were adjusted in advance as the film thickness in the formation of the film was about 100 nm.

Subsequently, in order to provide liquid crystal alignment regulating force by breaking a part of the molecular framework of the polymer compound with polarized light, polarized ultraviolet rays at a dominant wavelength of 280 nm were condensed and applied to the thin film using an ultraviolet ray lamp (a low-pressure mercury lamp), a wire grid polarizer, and an interference filter. After the application, such films were prepared: a film to which an ozone gas generated only around the ultraviolet ray lamp was forcedly blown for 30 minutes (this is referred to as a UV postprocess); and a film to which only ultraviolet rays were applied as in a Typical manner. After the preparation, such films were prepared: a film which foreign substances on the surface were removed by heating, drying, and the like (this is referred to as heat treatment); and a film to which no process was applied specifically.

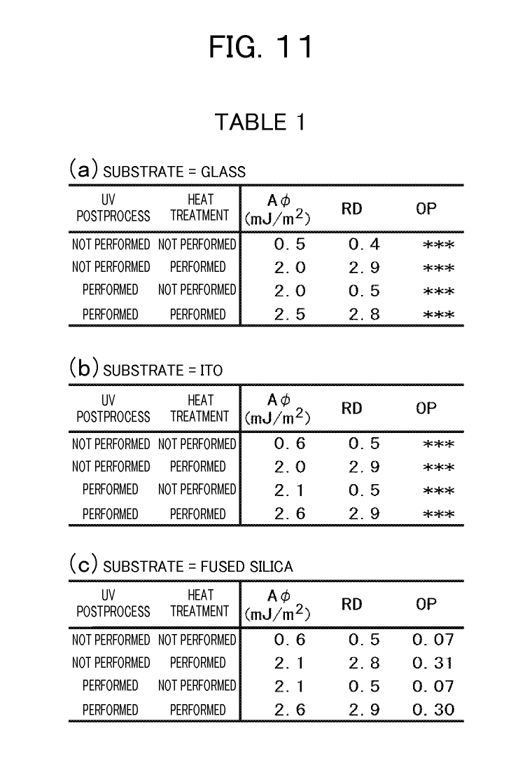

Table 1 illustrated in FIG. 11 is characteristic values of the obtained films (anchoring force Aφ, retardation RD, and an order parameter OP). Differences in the characteristic values caused by three types of substrates are rarely observed. When the UV postprocess was not performed and heat treatment was not performed, Aφ=0.5 to 0.6 mJ/m², whereas when the UV postprocess was not performed and heat treatment was performed, the anchoring force is increased as Aφ=2.0 to 2.1 mJ/m². Moreover, when the UV postprocess was performed and heat treatment was not performed, Aφ=2.0 to 2.1 mJ/m², whereas when the UV postprocess was performed and heat treatment was performed, Aφ=2.5 to 2.6 mJ/m², and the anchoring force is increased in both cases. In contrast to this, now observing the retardation values, when the UV postprocess was not performed and heat treatment was not performed, RD=0.4 to 0.5, whereas when the UV postprocess was not performed and heat treatment was performed, RD=2.8 to 2.9, and retardation is increased, that is, the optical anisotropy of the entire alignment film is increased.

Furthermore, when the UV postprocess was performed and heat treatment was not performed, RD=0.5, whereas when the UV postprocess was performed and heat treatment was performed, RD=2.8 to 2.9, and retardation is increased by heat treatment, that is, the optical anisotropy of the entire alignment film is increased. Similarly, although only in the case of the fused silica substrate (in the other substrates, the absorption of the substrates overlaps the absorption of the alignment film), in the observation of the order parameters, when the UV postprocess was not performed and heat treatment was not performed, OP=0.07, whereas when the UV postprocess was not performed and heat treatment was performed, RD=0.31, and the order parameter is increased, that is, the optical anisotropy of the entire alignment film is increased.

In addition, when the UV postprocess was performed and heat treatment was not performed, OP=0.07, whereas when the UV postprocess was performed and heat treatment was performed, OP=0.30, and retardation is increased by heat treatment, that is, the optical anisotropy of the entire alignment film is increased. In reviewing the combinations, such a film was formed that the anchoring force proportional to the liquid crystal alignment regulating force was high and optical anisotropy was small in the entire film only when the UV postprocess was performed and heat treatment was not performed.

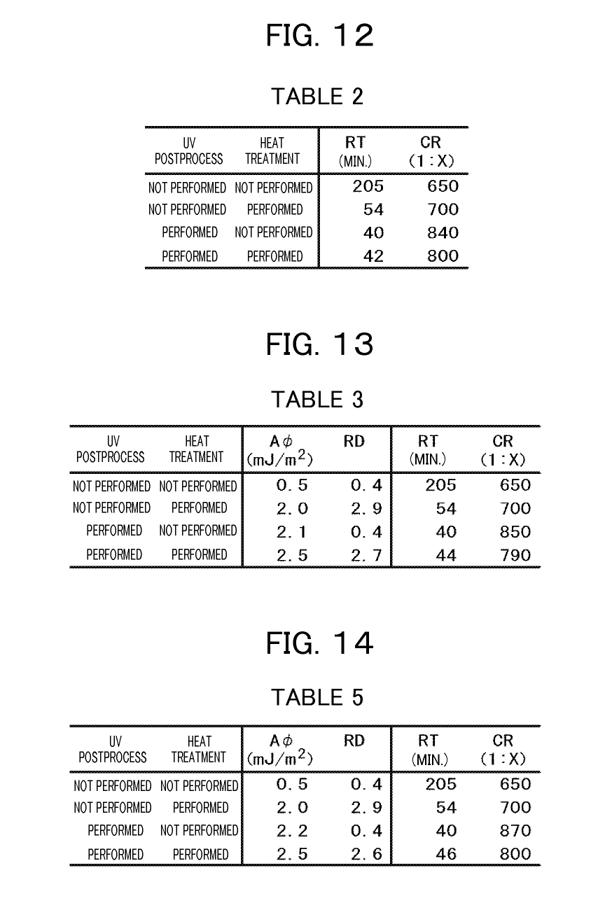

Moreover, an IPS mode liquid crystal display device was prepared using alignment films prepared in these four combinations, and characteristics of the liquid crystal display device (a luminance relaxation constant RT and a contrast CR) were measured. Table 2 in FIG. 12 is results. First, in observing the luminance relaxation constant, when the UV postprocess was not performed and heat treatment was not performed, RT=205 minutes, whereas when the UV postprocess was not performed and heat treatment was performed, RT=54 minutes, and the afterglow characteristics were improved. When the UV postprocess was performed and heat treatment was not performed, RT=40 minutes. When the UV postprocess was performed and heat treatment was not performed, RT=42 minutes, and the afterglow characteristics were improved.

On the other hand, in observing the contrast (the value X in the ratio 1:X), when the UV postprocess was not performed and heat treatment was not performed, CR=650, whereas when the UV postprocess was not performed and heat treatment was performed, CR=700, and the afterglow characteristics were improved. When the UV postprocess was performed and heat treatment was not performed, CR=840. When the UV postprocess was performed and heat treatment was not performed, CR=800, and the contrast characteristic was improved. In reviewing the combinations, a film showing high display performance that afterglow time was short and the contrast was also high was obtained when the UV postprocess was performed and heat treatment was not performed.

From the description above, it was confirmed that an ozone gas is used in performing the photo-alignment process and such a film is obtained that the liquid crystal alignment regulating force is high and the optical anisotropy of the entire film is small as well as the performance of the liquid crystal display device is improved.

### Second Embodiment

Next, a result confirming that such a film is obtained that the liquid crystal alignment regulating force is high and the optical anisotropy of the entire film is small as well as the performance of the liquid crystal display device is improved under different preparation conditions will be described with reference to the drawing and a table.

The same material as in the first embodiment was used for an alignment film material, alignment films were coated, imidized, and burned under the similar preparation conditions, and the alignment process or heat treatment was performed using the same polarized ultraviolet light source. Points different from the first embodiment are in that for the UV postprocess, these thin films were immersed in a hydrogen peroxide solution (3%) for one minute and subjected to pure water shower cleaning. A substrate for physical properties was only a glass substrate, and liquid crystal display devices were prepared also under the same conditions.

Table 3 illustrated in FIG. 13 is the characteristics of the obtained films. In Table 3, values when the UV postprocess was not performed and heat treatment was not performed and values when the UV postprocess was not performed and heat treatment was performed are the same as the values in the first embodiment. The effect of the UV postprocess in the second embodiment can be compared between values when the UV postprocess was performed and heat treatment was not performed and values when the UV postprocess was performed and heat treatment was performed. In observing the values, a tendency similar to the first embodiment is recognized. Such a film was formed that the anchoring force proportional to the liquid crystal alignment regulating force was high and optical anisotropy was small in the entire film only when the UV postprocess was performed and heat treatment was not performed. Moreover, similarly, a film showing high display performance that afterglow time was short and the contrast was also high was obtained when the UV postprocess was performed and heat treatment was not performed.

From the description above, it was confirmed that a hydrogen peroxide solution is used in performing the photo-alignment process and such a film is obtained that the liquid crystal alignment regulating force is high and the optical anisotropy of the entire film is small as well as the performance of the liquid crystal display device is improved.

### Third Embodiment

Next, a result confirming that such a film is obtained that the liquid crystal alignment regulating force is high and the optical anisotropy of the entire film is small as well as the performance of the liquid crystal display device is improved under different preparation conditions will be described with reference to the drawing and a table.

The same material in the first embodiment was used for an alignment film material, alignment films were coated, imidized, and burned under the similar preparation conditions, and the alignment process or heat treatment was performed using the same polarized ultraviolet light source. Points different from the first embodiment are in that for UV postprocess, these thin films were immersed in a hypochlorous acid solution (20 ppm) for 30 seconds and subjected to pure water shower cleaning. A substrate for physical properties was only a glass substrate, and liquid crystal display devices were prepared also under the same conditions.

Table 5 illustrated in FIG. 14 is the characteristics of the obtained films. In the characteristics, values when the UV postprocess was not performed and heat treatment was not performed and values when the UV postprocess was not performed and heat treatment was performed are the same as the values in the first embodiment. The effect of the UV postprocess in the fourth embodiment can be compared between values when the UV postprocess was performed and heat treatment was not performed and values when the UV postprocess was performed and heat treatment was performed. In observing the values, a tendency similar to the first embodiment is recognized. Such a film was formed that the anchoring force proportional to the liquid crystal alignment regulating force was high and optical anisotropy was small in the entire film only when the UV postprocess was performed and heat treatment was not performed. Moreover, similarly, a film showing high display performance that afterglow time was short and the contrast was also high was obtained when the UV postprocess was performed and heat treatment was not performed.

From the description above, it was confirmed that a hypochlorous acid solution is used in performing the photo-alignment process and such a film is obtained that the liquid crystal alignment regulating force is high and the optical anisotropy of the entire film is small as well as the performance of the liquid crystal display device is improved.

### Fourth Embodiment

Next, a result confirming that such a film is obtained that the liquid crystal alignment regulating force is high and the optical anisotropy of the entire film is small under different preparation conditions will be described with reference to the drawing and a table.

Comparative examples were prepared in which the same material in the first embodiment was used for an alignment film material, alignment films were coated, imidized, and burned under the similar preparation conditions, and subjected to the alignment process or heat treatment at various temperatures (a temperature of 100 to 240° C. for 20 minutes) using the same polarized ultraviolet light source. In contrast to this, the case where a process of a hypochlorous acid solution (1 ppm) was performed after the alignment process similarly to the third embodiment was compared with the case where a process of hypochlorous acid solution (1 ppm) was performed after the alignment process and then heat treatment similarly to the third embodiment. A silica substrate was used for a substrate for physical properties, and the anchoring force Aφ (mJ/m²), the retadation RD (nm), the order parameter OP, and the surface roughness (root mean square, nm) were evaluated when the alignment films were used.

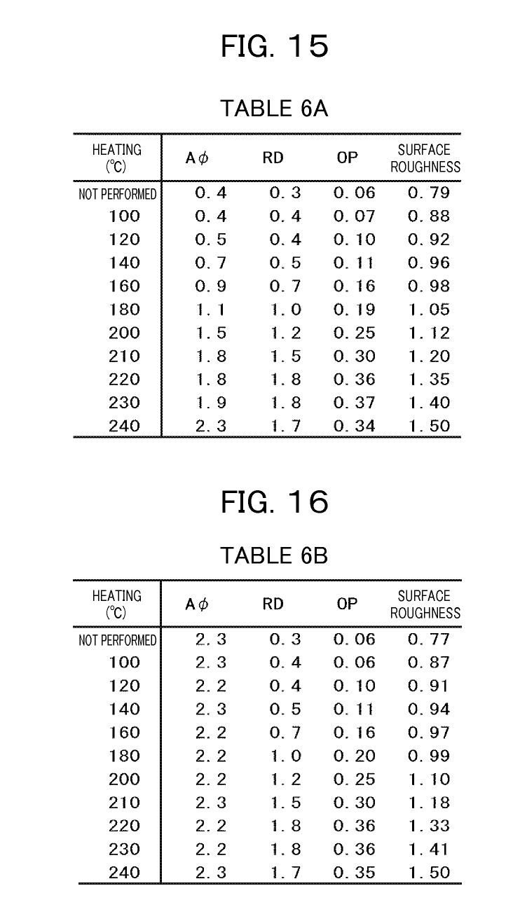

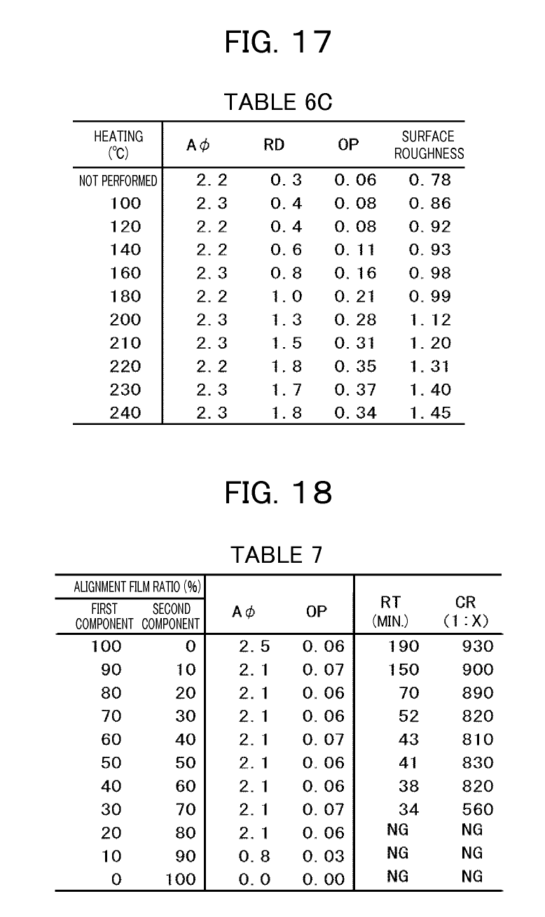

Table 6A illustrated in FIG. 15 is the case where only heat treatment was performed, Table 6B illustrated in FIG. 16 is the case where heat treatment was performed after hypochlorous acid solution processing, and Table 6C illustrated in FIG. 17 is the case where hypochlorous acid solution processing was performed after heat treatment. From Tables 6A, 6B, and 6C, in the case of the film subjected only to heat treatment, it is necessary to heat the film at a temperature of 180° C. or more in order to form a film having a high alignment regulating force at an anchoring force of 1.0 mJ/m² or more. However, retardation in this heating is 1.0 μm, the order parameter is 0.19, and the surface roughness is 1.05 nm. Anisotropy is produced in the inside of the film, and a certain surface roughness is observed.

A highly excellent anchoring force is exhibited in the case of a heating temperature of 240° C., and the anchoring force at this time is 2.3 mJ/m². However, retardation is 1.7 μm, the order parameter is 0.34, and the surface roughness is 1.50. The anisotropy in the inside of a single layer film is increased, and the surface roughness is also increased. In contrast to this, in the case where hypochlorous acid solution processing was performed, the anchoring force is a high alignment regulating force of 2.2 to 2.3 mJ/m² regardless of performing heat treatment. When a heating temperature is a temperature of 180° C. or less, a highly flat film having a surface roughness of 1.0 nm or less is formed. When a heating temperature is a temperature of 160° C. or less, such a film is formed that the anisotropy in the inside of the film is small and retardation is smaller than 1.0 μm. When a heating temperature is a temperature of 120° C. or less, such a film is formed that the anisotropy in the inside of a single layer film is small and the order parameter is 0.10 or less.

From the description above, it was confirmed that the combination of appropriately heat treatment and hypochlorous acid solution is used and such a film is obtained that the liquid crystal alignment regulating force is high and the optical anisotropy of the entire film is small as well as the performance of the liquid crystal display device is improved.

### Fifth Embodiment

Next, a result confirming that such a film is obtained that the liquid crystal alignment regulating force is high and the optical anisotropy of the entire film is small under different preparation conditions will be described with reference to the drawing and a table.

Here, for the alignment film material, the same components as the first embodiment were used for the component of a first alignment film and the component of a second alignment film. However, here, these alignment films were not formed by coating for one time using a mixture of the components. The components of the alignment films were separately coated and imidized for coating in layers, and the concentrations of the liquid solutions of the alignment films in coating were adjusted to change the film thicknesses of the components of the alignment films. The concentrations of the liquid solutions and the printing conditions were studied for the component alone on the alignment films in advance. The films were prepared under such conditions that the total film thickness of two types of alignment films was 100 nm and the ratio was within 3% of the set film thickness. The resistivity of the component alone on the alignment films was measured, the component of the first alignment film had a resistivity of 7.0×10¹⁵ Ωcm, and the component of the second alignment film had a resistivity of 2.4×10¹⁴ Ωcm.

The specific preparation conditions for the thin films are as follows. A silica substrate was used for a substrate. After cleaning the substrate similarly to the first embodiment, first, a thin film was formed on the base substrate by flexographic printing with the precursor of the component of the second alignment film, temporarily dried at a temperature of 40° C. or more, and imidized in a baking furnace at a temperature of 150° C. or more. After the processes, a thin film was formed on the thin film by flexographic printing with the precursor of the component of the first alignment film, temporarily dried at a temperature of 40° C. or more, and imidized in a baking furnace at a temperature of 150° C. or more. Subsequently, polarized ultraviolet rays at a dominant wavelength of 280 nm were condensed and applied. After the application, hypochlorous acid solution processing was performed similarly to the third embodiment.

Table 7 illustrated in FIG. 18 is the anchoring force Aφ (mJ/m²) and the order parameter OP of the obtained alignment films. From Table 7, when the component of the first alignment film is in a range of 20 to 100%, high values of the anchoring force of 2.1 to 2.2 mJ/m² are obtained. At 10%, the anchoring force is decreased to 0.8 mJ/m², and at 0%, the alignment regulating force was not detected. In contrast, as for the order parameter, values are small as 0.07 or less at any ratios, and it can be confirmed that the optical anisotropy of all the films is small.

Next, an IPS mode liquid crystal display device similarly to the first embodiment was prepared, and characteristics of the liquid crystal display device (a luminance relaxation constant RT and a contrast CR) were measured. The result is shown in Table 7 similarly. From Table 7, the luminance relaxation constant was more decreased as the component of the first alignment film was more dropped from 100%, and low afterglow characteristics of 34 to 52 hours were exhibited in a range of 30 to 70%. In contrast to this, the contrast was more decreased as the component of the first alignment film is more dropped from 100%, and the contrast of 820 to 890 was exhibited in a range of 40 to 70%. In this connection, when the component of the first alignment film was 20% or less, it was not possible to prepare a display device of uniform liquid crystal alignment and it was not possible to measure panel characteristics. It is noted that in Table 7, NG expresses that it was not possible to form uniform alignment films and it was not possible to measure panel characteristics.

From the description above, it was confirmed that even in the photo-alignment film in the two-layer structure in which two types of alignment films are stacked, formed of a photo-alignable photo-alignment upper layer and a low resistive under layer having a resistivity lower than the resistivity of the photo-alignment upper layer, such a film is obtained that the liquid crystal alignment regulating force is high and the optical anisotropy of the entire film is small as well as the performance of the liquid crystal display device is improved.

### Sixth Embodiment

Next, a result will be described with reference to the drawing and a table in which the entire processes of preparing a liquid crystal display device were closely investigated and heat treatment temperatures and display characteristics were studied from the process after the process of polarized ultraviolet irradiation to the alignment film to the process of attaching the TFT substrate to the counter substrate.

FIG. 7 is the processes of preparing the liquid crystal display device according to an embodiment of the present invention. In the processes, heat treatment is necessary in the leveling process, the imidization reaction, the postirradiation process (in the case where heating is necessary), a process of attaching the upper substrate to the lower substrate (a process that a sealing agent is drawn on the portion around the liquid crystal panel and the substrates are attached to each other and thermoset by heating), a process of filling the liquid crystal (in the case where heating is necessary in order to decrease the liquid crystal viscosity), and a process of sealing end portions (as similar to attaching the upper substrate to the lower substrate, in order to thermoset the sealing agent and a cell aging process in which in order to fit the filled liquid crystal to the alignment films, a cell is once heated at the liquid crystal-to-isotropic phase transition temperature of the liquid crystal or above, and then gradually cooled).

In the case where the liquid crystal display devices according to the embodiments are prepared, it is necessary to subject the liquid crystal display devices to these preparation processes. Only changes in the characteristics are shown so far when various preparation conditions are changed in the preparation of the liquid crystal alignment films. In other words, attention is focused on the postirradiation process only when the heating conditions are changed (in the case where heating is necessary), and the standard conditions are used for the other processes.

The standard conditions used in the embodiment here are as follows. The leveling process is performed at a temperature of 40 to 80° C. for about one to five minutes. The imidization reaction is performed at a temperature of 210 to 230° C. for about 10 to 20 minutes. For the sealing agent in the process of attaching the upper substrate to the lower substrate and the process of attaching the seal end portions, an acrylic epoxy sealing agent is used for ultraviolet curing and the sealing agent is cured by postbaking at a temperature of 120° C. for 60 minutes. In the cell aging process, the cell is heated at a temperature of 100° C., which is the phase transition point or more of the nematic liquid crystal used, for 60 minutes.

In the processes, investigations were made on the relationship of the display characteristics to the sealing agent heat treatment temperatures in attaching the upper substrate to the lower substrate and attaching seal end portions and the cell aging temperatures for heat treatment temperatures after the process of applying polarized ultraviolet rays to the alignment film, and it was revealed that new display failures occur. More specifically, the relationship of the display characteristics to the sealing agent heat treatment temperatures and the cell aging temperatures was investigated using liquid crystal display panels prepared under the conditions that the UV postprocess was performed and heat treatment was not performed in the first embodiment.

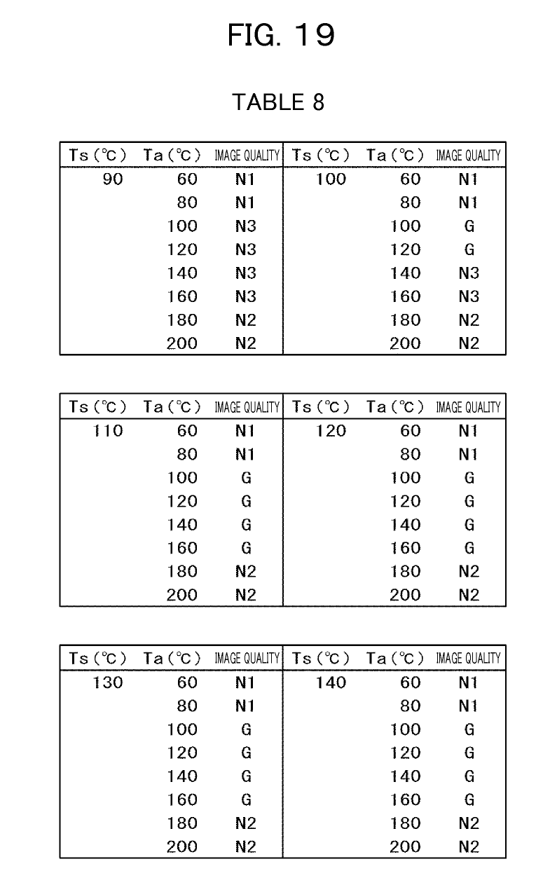

Table 8 illustrated in FIG. 19 is the evaluation result. In Table 8, the notation NI expresses a failure that unevenness is observed in the orientation state in the inside of the display pixel through a polarizing microscope. The notation N2 expresses a failure that dim, egg-laying unevenness is visually observed on throughout the panel surface. The notation N3 expresses a failure that dim unevenness scattering around the panel is visually observed.

First, the seal curing temperature (in the following, denoted as Ts) was fixed to the standard conditions, and the cell aging temperature (in the following, denoted as Ta) was increased from a temperature of 60° C. to a temperate of 200° C. in steps of a temperature of 20° C. When Ta was at a temperature of 80° C. or less, a failure was confirmed that unevenness was observed in the orientation state in the inside of the display pixel through the polarizing microscope, whereas when Ta was at a temperature of 100 to 160° C., a display failure was not observed specifically (in the following, denoted as good, G). When Ta was at a temperature of 180° C. or more, a failure was observed that dimly scattering unevenness was visually observed on throughout the panel surface scattered (in the following, denoted as failure N2). This failure N2 was worse at a temperature of 200° C. than at a temperature of 180° C.

Therefore, Table 8 is the results of the evaluation of the display characteristics that the seal curing temperature (Ts) was changed from a temperature of 90° C. to a temperature of 140° C. in steps of a temperature of 10° C. and Ta was similarly changed in a range of a temperature of 60 to 200° C. From Table 8, when Ts was at a temperature of 90° C., the failure NI was observed at a temperature of 60 to 80° C. At a temperature of 100 to 160° C., a failure was observed that dim unevenness scattering around the panel was visually observed (in the following, denoted as failure N3). At a temperature of 180 to 200° C., failure N2 was observed, and it was not possible to obtain any excellent display characteristics at any temperatures. When Ts was at a temperature of 100° C., Ta exhibited a good result, G, at a temperature of 100 to 120° C., whereas Ta was at other temperatures, the same results were exhibited at a temperature of 90° C. When Ts was at a temperature of 110 to 140° C., the temperature and display characteristics of Ta were exhibited similarly to the case where Ts was at a temperature of 120° C.

Although the causes of such failures of the display characteristics are not clear, it can be considered that failure N1 is a liquid crystal alignment failure caused by insufficiency of so-called liquid crystal cell aging, and it can be considered that failure N3 is affected by the diffusion of impurities from the sealing agent to the liquid crystal because failure N3 occurs around the panel. Although failure N2 is a failure that occurs at considerably higher temperatures, the causes are unknown.

From the description above, it was revealed that when the heat treatment temperature is a temperature of 180° C. or more from the process after the process of applying polarized ultraviolet rays to the alignment film to the process of attaching the TFT substrate to the counter substrate, display failures from unknown causes occurred and it was not possible to obtain an excellent liquid crystal display device at a temperature lower than a temperature of 100° C.

What is claimed is:

1. A liquid crystal display device comprising:
a TFT substrate having a pixel electrode and a first photo alignment film;
a counter substrate disposed opposite to the TFT substrate and having a second photo alignment film; and
a liquid crystal disposed between the first alignment film and the second alignment film,
wherein a surface of the first photo alignment film has liquid crystal alignment force, and optical anisotropy of the first photo alignment film is smaller than 1.0 nm in a retardation value.

2. A liquid crystal display device comprising:
a TFT substrate having a pixel electrode and a first alignment film;
a counter substrate disposed opposite to the TFT substrate and having an second alignment film; and
a liquid crystal disposed between the first alignment film and the second alignment film,
wherein a topmost surface layer of the first photo alignment film has liquid crystal alignment regulating force, and optical anisotropy of the first photo alignment film is 0.1 or less in an order parameter.

3. The liquid crystal display device according to claim 1,
wherein the alignment force on the surface of the first photo alignment film has an anchoring strength of 1.0×10³ J/m² or greater.

4. The liquid crystal display device according to claim 2,
wherein the alignment regulating force on the surface of the first photo alignment film has an anchoring strength of 1.0×10⁻³ J/m² or greater.

5. The liquid crystal display device according to claim 1,
wherein a size of a surface irregularity of the first photo alignment film is one nanometer or less in a root mean square.

6. The liquid crystal display device according to claim 2,
wherein a size of a surface irregularity of the first photo alignment film is one nanometer or less in a root mean square.

7. The liquid crystal display device according to claim 1,
wherein optical anisotropy of the second photo-alignment film is smaller than 1.0 nm in a retardation value.

8. The liquid crystal display device according to claim 2,
wherein optical anisotropy of the second photo-alignment film is smaller than 1.0 nm in a retardation value.

9. The liquid crystal display device according to claim 1,
wherein the first photo alignment film is a photodecomposition type photo-alignment film.

10. The liquid crystal display device according to claim 2,
wherein the first photo alignment film is a photodecomposition type photo-alignment film.

11. The liquid crystal display device according to claim 1,
wherein the first photo alignment film is a photodecomposition type photo-alignment film containing polyimide given by Chemical formula 1 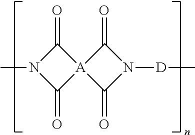
where a formula in brackets expresses a chemical structure of a repetition unit, numerical subscript n expresses a number of the repetition unit, N expresses a nitrogen atom, O expresses an oxygen atom, A expresses a quadrivalent organic group containing a cyclobutane ring, and D expresses a divalent organic group.

12. The liquid crystal display device according to claim 2,
wherein the first photo alignment film is a photodecomposition type photo-alignment film containing polyimide given by Chemical formula 1 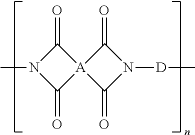
where a formula in brackets expresses a chemical structure of a repetition unit, numerical subscript n expresses a number of the repetition unit, N expresses a nitrogen atom, O expresses an oxygen atom, A expresses a quadrivalent organic group containing a cyclobutane ring, and D expresses a divalent organic group.

13. The liquid crystal display device according to claim 1,
wherein the first photo alignment film is a two-layer structure formed of a photo-alignable photo-alignment upper layer and a low resistive under layer having a resistivity lower than a resistivity of the photo-alignment upper layer.

14. The liquid crystal display device according to claim 2,
wherein the alignment film is a two-layer structure formed of a photo-alignable photo-alignment upper layer and a low resistive under layer having a resistivity lower than a resistivity of the photo-alignment upper layer.

15. The liquid crystal display device according to claim 1,
wherein the liquid crystal display device is an IPS mode liquid crystal display device.

16. The liquid crystal display device according to claim 2,
wherein the liquid crystal display device is an IPS mode liquid crystal display device.

17. A manufacturing method of a liquid crystal display device including a TFT substrate having a pixel electrode and a TFT and formed with an alignment film; a counter substrate disposed opposite to the TFT substrate and formed with an alignment film on the TFT substrate side; and a liquid crystal sandwiched between the alignment film of the TFT substrate and the alignment film of the counter substrate, the method comprising the steps of:
preparing the TFT substrate having the pixel electrode and the TFT;
forming the alignment film on the TFT substrate or the counter substrate;
applying a polarized ultraviolet ray to the alignment film and then oxidizing the alignment film;
attaching the TFT substrate attached with the alignment film provided with alignment regulating force to the counter substrate; and
filling a liquid crystal between the TFT substrate and the counter substrate in the attaching step or after the attaching step.

18. The manufacturing method of a liquid crystal display device according to claim 17,
wherein: a cross-linker is added in the alignment film; and
cross-linking is performed after the step of applying the polarized ultraviolet ray to the alignment film to the step of attaching the TFT substrate to the counter substrate.

19. The manufacturing method of a liquid crystal display device according to claim 17,
wherein heat treatment is not performed at a temperature of 180° C. or more after the step of applying the polarized ultraviolet ray to the alignment film to the step of attaching the TFT substrate to the counter substrate.

20. The manufacturing method of a liquid crystal display device according to claim 19,
wherein heat treatment is not performed at a temperature of 120° C. or more after the step of applying the polarized ultraviolet ray to the alignment film to the step of attaching the TFT substrate to the counter substrate.
